(19) United States
(12) Patent Application Publication
(10) Pub. No.: US 2026/0130052 A1
(43) Pub. Date: May 7, 2026

(54) DISPLAY APPARATUS AND ELECTRONIC DEVICE

(71) Applicant: Samsung Display Co., LTD., Yongin-si (KR)

(72) Inventors: Jonghyun Yun, Yongin-si (KR); Hyunwoo Kang, Yongin-si (KR); Daegi Kweon, Yongin-si (KR); Junyoung Kim, Yongin-si (KR); Jina Park, Yongin-si (KR); Yongho Yang, Yongin-si (KR); Kyungmin Lee, Yongin-si (KR); Changho Jeong, Yongin-si (KR); Youngin Hwang, Yongin-si (KR)

(21) Appl. No.: 19/307,634

(22) Filed: Aug. 22, 2025

(30) Foreign Application Priority Data
Nov. 4, 2024 (KR) 10-2024-0154437

(51) Int. Cl. H10K 59/122

(52) U.S. Cl. CPC H10K 59/122

(57) ABSTRACT

A display apparatus includes a pixel electrode arranged on the substrate and including an emission area and a connection area, a pixel-defining layer having a pixel opening exposing the emission area of the pixel electrode, a spacer arranged on the pixel-defining layer and having a spacer opening overlapping the pixel opening and exposing the emission area of the pixel electrode, and an intermediate layer and an opposite electrode, which cover the spacer and cover the pixel electrode exposed by the pixel opening and the spacer opening. The connection area is arranged on a portion of a perimeter of the emission area. In the emission area, the spacer opening is larger than the pixel opening, and in the connection area, the spacer opening is smaller than the pixel opening.

### CROSS-REFERENCE TO RELATED APPLICATION

This application is based on and claims priority under 35 U.S.C. § 119 to Korean Patent Application No. 10-2024-0154437, filed on Nov. 4, 2024, in the Korean Intellectual Property Office, the disclosure of which is incorporated by reference herein in its entirety.

### BACKGROUND

### 1. Field

One or more embodiments relate to an apparatus, and more particularly, to a display apparatus and an electronic device.

### 2. Description of the Related Art

Display apparatuses visually display data. Display apparatuses are used as displays for small products, such as mobile phones, and are also used as displays for large products, such as televisions.

Some layers included in a display apparatus are provided in common for a plurality of display elements. Therefore, when current is supplied to one display element, current is also supplied to other adjacent display elements, and thus, the color purity of the display apparatus may deteriorate.

The above-mentioned background art is technical information that the inventor possessed for derivation of the disclosure or acquired in the process of derivation of the disclosure, and cannot necessarily be said to be a known technique disclosed to the general public prior to the filing of the disclosure.

### SUMMARY

However, such existing display apparatuses require an additional process to prevent leakage current.

In order to solve various problems including the above problems, one or more embodiments include a display apparatus and an electronic device in which leakage current may be reduced and process operations may be minimized, so as to prevent a current concentration phenomenon from occurring.

However, it should be understood that embodiments described herein should be considered in a descriptive sense only and not for limitation of the disclosure.

Additional aspects will be set forth in part in the description which follows and, in part, will be apparent from the description, or may be learned by practice of the presented embodiments of the disclosure.

According to one or more embodiments, a display apparatus includes a pixel electrode arranged on the substrate and including an emission area and a connection area, a pixel-defining layer having a pixel opening exposing the emission area of the pixel electrode, a spacer arranged on the pixel-defining layer and having a spacer opening overlapping the pixel opening and exposing the emission area of the pixel electrode, and an intermediate layer and an opposite electrode, which cover the spacer and cover the pixel electrode exposed by the pixel opening and the spacer opening, wherein the connection area is arranged on a portion of a perimeter of the emission area, and wherein, in the emission area, the spacer opening is larger than the pixel opening, and in the connection area, the spacer opening is smaller than the pixel opening.

The pixel opening may include a first main opening overlapping the emission area and a connection opening overlapping the connection area, wherein the connection opening may extend outward from the first main opening.

The first main opening may have a polygonal shape, and the connection opening may be arranged at a corner of the polygonal shape.

In a plan view, a perimeter of the spacer opening may cross the connection opening.

The spacer may not be arranged in the emission area, and a portion of the spacer may be arranged in the connection area.

The spacer opening may include a second main opening overlapping the emission area and a protruding opening overlapping the connection area, wherein the protruding opening may protrude inwardly from a perimeter of the second main opening.

The second main opening may have one of a circular shape and an annular shape, and a plurality of protruding openings may be separated from each other along the perimeter of the second main opening.

The spacer may include a tail portion that is separated inwardly from a perimeter of the spacer opening in a plan view and extends along the perimeter of the spacer opening.

The tail portion may be arranged on the perimeter of the emission area and may not be arranged in the connection area.

In a plan view, the tail portion may be arranged between the perimeter of the spacer opening and a perimeter of the pixel opening.

According to one or more embodiments, a display apparatus includes a substrate, a pixel electrode arranged on the substrate and including an emission area and a connection area, a pixel-defining layer having a pixel opening exposing the emission area of the pixel electrode, a spacer arranged on the pixel-defining layer and having a spacer opening overlapping the pixel opening and exposing the emission area of the pixel electrode, and an intermediate layer and an opposite electrode, which cover the spacer and cover the pixel electrode exposed by the pixel opening and the spacer opening, wherein the connection area is arranged on a portion of a perimeter of the emission area, and wherein the spacer is arranged on a portion of an upper surface of the pixel-defining layer around the perimeter of the emission area, and the spacer is arranged in the connection area to completely cover the upper surface and side surfaces of the pixel-defining layer.

The pixel-defining layer may be tapered in a reverse shape so as to be inclined toward a center of the emission area as a distance increases upward from the substrate.

A first angle formed between an inner surface of the pixel-defining layer defining the pixel opening and an upper surface of the substrate may be in a range of about 90° to about 170°.

The spacer may be tapered in a normal shape to be inclined in a direction away from a center of the emission area as a distance increases upward from the substrate.

A second angle formed between an inner surface of the spacer defining the spacer opening and the substrate may be in a range of more than 0° and less than or equal to 80°.

The intermediate layer and the opposite electrode may be disconnected around the perimeter of the emission area, so that a portion of the intermediate layer arranged on the pixel electrode may be separated from a portion of the intermediate layer arranged on an upper surface of the spacer and a portion of the opposite electrode arranged on the pixel electrode may be separated from a portion of the opposite electrode arranged on the upper surface of the spacer.

The intermediate layer and the opposite electrode may cover a side surface of the spacer opening in the connection area, a portion of the intermediate layer arranged on the pixel electrode may be connected to a portion of the intermediate layer arranged on an upper surface of the spacer, and a portion of the opposite electrode arranged on the pixel electrode may be connected to a portion of the opposite electrode arranged on the upper surface of the spacer.

The spacer may include a tail portion arranged inside the pixel opening along the perimeter of the emission area.

The tail portion may be arranged between a side surface of the pixel-defining layer defining the pixel opening and the pixel electrode.

A third angle formed between a side surface of the tail portion facing a center of the emission area and an upper surface of the substrate may be in a range of about 30° to about 70°.

In the emission area, the intermediate layer and the opposite electrode may be settled on the side surface of the tail portion.

According to one or more embodiments, a display apparatus includes a substrate including a first area, a second area surrounding at least a portion of the first area, and a third area between the first area and the second area, a pixel electrode arranged in the second arera, a pixel-defining layer having a pixel opening exposing a portion of the pixel electrode, a spacer arranged on the pixel-defining layer and having a spacer opening overlapping the pixel opening, an intermediate layer arranged on the spacer, and a separator arranged in the third area, wherein the separator may include a body portion in a reverse shape, which is arranged on the substrate, and a body tail portion arranged between an inclined side surface of the body portion and the substrate.

The body portion may include a same material as the pixel-defining layer.

The body tail portion may include a same material as the spacer.

The intermediate layer may be disconnected or separated by the separator in the third area.

According to one or more embodiments, an electronic device includes a display apparatus, and a housing accommodating the display apparatus therein, wherein the display apparatus may include a substrate, a pixel electrode arranged on the substrate and including an emission area and a connection area, a pixel-defining layer having a pixel opening exposing the emission area of the pixel electrode, a spacer arranged on the pixel-defining layer and having a spacer opening overlapping the pixel opening and exposing the emission area of the pixel electrode, and an intermediate layer and an opposite electrode, which cover the spacer and cover the pixel electrode exposed by the pixel opening and the spacer opening, wherein the connection area may be arranged on a portion of a perimeter of the emission area, and wherein, in the emission area, the spacer opening may be larger than the pixel opening, and in the connection area, the spacer opening may be smaller than the pixel opening.

Other aspects, features and advantages other than those described above will become apparent from the following detailed description, claims and drawings for practicing the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of an electronic device according to an embodiment;

FIG. 2 is a schematic cross-sectional view of an electronic device according to an embodiment, and is a cross-sectional view of the electronic device taken along line II-II′ of FIG. 1;

FIG. 3 is a schematic plan view of a display apparatus according to an embodiment;

FIGS. 4 and 5 are equivalent circuit diagrams of a pixel included in a display apparatus according to embodiments;

FIG. 6 is a plan view of a portion of a display apparatus according to an embodiment;

FIGS. 7 to 10 are schematic enlarged plan views of a portion of a display apparatus according to an embodiment, and illustrate an area VII of FIG. 6;

FIG. 11 is a schematic cross-sectional view of the display apparatus taken along line XI-XI′ of FIG. 10;

FIG. 12 is a schematic cross-sectional view of the display apparatus taken along line XII-XII′ of FIG. 10;

FIG. 13 is a schematic enlarged plan view of a portion of a display apparatus according to an embodiment; and

FIG. 14 is a schematic cross-sectional view of the display apparatus taken along line XIV-XIV′ of FIG. 6.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the present embodiments, and a method to achieve the same, will be clearer referring to the detailed descriptions below with the drawings. However, the present embodiments may be implemented in various forms, not by being limited to the embodiments presented below.

Hereinafter, embodiments will be described, in detail, with reference to the accompanying drawings, and in the description with reference to the drawings, the same or corresponding components are indicated by the same reference numerals and redundant descriptions thereof are omitted.

In the following embodiment, it will be understood that although the terms “first,” “second,” etc. may be used herein to describe various components, these components should not be limited by these terms. These terms are only used to distinguish one component from another.

In the following embodiment, the expression of singularity in the specification includes the expression of plurality unless clearly specified otherwise in context.

In the following embodiment, it will be further understood that the terms “includes,”, “has,” “including,” and/or “having” used herein specify the presence of stated features or components, but do not preclude the presence or addition of one or more other features or components.

In the following embodiment, it will be understood that when a layer, region, or component is referred to as being “formed on” another layer, region, or component, it can be directly or indirectly formed on the other layer, region, or component. That is, for example, intervening layers, regions, or components may be present.

In the following embodiments, when layers, regions, or components are connected to each other, the layers, the regions, or the components may be directly connected to each other, or another layer, another region, or another component may be interposed between the layers, the regions, or the components and thus the layers, the regions, or the components may be indirectly connected to each other. In addition, when layers, regions, or components are electrically connected to each other, the layers, the regions, or the components may be directly electrically connected to each other, or another layer, another region, or another component may be interposed between the layers, the regions, or the components and thus the layers, the regions, or the components may be indirectly electrically connected to each other.

Sizes of elements in the drawings may be exaggerated for convenience of explanation. In other words, since sizes and thicknesses of components in the drawings are arbitrarily illustrated for convenience of explanation, the following embodiments are not limited thereto.

In the following embodiments, the expression such as “A and/or B” may include A, B, or A and B. Furthermore, the expression such as “at least one of A and B” may include A, B, or A and B.

As used herein, when a wiring is referred to as “extending in a first direction or a second direction,” it means that the wiring not only extends in a straight line shape but also extends in a zigzag or in a curve in the first direction or the second direction.

As used herein, “in a plan view” means that an objective portion is viewed from above. In addition, “in a cross-sectional view” means that a cross-section of an objective portion taken vertically is viewed from a lateral side. In the following embodiments, “overlapping” of a first component and a second component means that the first component is located above or below the second component.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

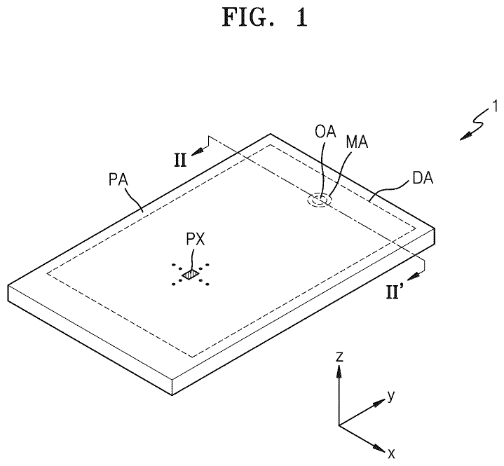

FIG. 1 is a schematic perspective view of an electronic device 1 according to an embodiment.

Referring to FIG. 1, the electronic device 1 is a device for displaying a moving image or still image, and may be used as a display screen for various products including not only portable electronic devices, such as mobile phones, smart phones, tablet personal computers (PCs), mobile communication terminals, electronic organizers, electronic books, portable multimedia players (PMPs), navigation devices, ultra-mobile PCs (UMPCs), and the like, but also televisions, notebook computers, monitors, billboards, internet of things (IOT) device, and the like. Furthermore, the electronic device 1 according to an embodiment may be used in wearable devices, such as smart watches, watch phones, glasses type displays, and head mounted displays (HMDs). Furthermore, the electronic device 1 according to an embodiment may be applied to an instrument panel of a vehicle, and a center information display (CID) arranged in a center fascia or dashboard of a vehicle, a room mirror display in lieu of a side mirror of a vehicle, and a display screen arranged on the backside of the front seat as an entertainment for the rear seat of a vehicle. FIG. 1 shows that the electronic device 1 according to an embodiment is used as a smart phone for convenience of description.

The electronic device 1 may have a generally rectangular shape in a plan view. For example, the electronic device 1 may have a generally rectangular planar shape having a short side in an x direction and a long side in a y direction, as illustrated in FIG. 1. A corner where the short side in the x direction and the long side in the y direction meet may be round to have a certain curvature or may be formed at a right angle. The planar shape of the electronic device 1 is not limited to a generally rectangular shape, and may be other polygonal, elliptical, or atypical shapes.

The electronic device 1 may include an opening area OA and a display area DA that at least partially surrounds the opening area OA. The electronic device 1 may include an intermediate area MA positioned between the opening area OA and the display area DA, and may further include a peripheral area PA positioned outside the display area DA, for example, surrounding the display area DA. The intermediate area MA may have a closed-loop shape completely surrounding the opening area OA in a plan view.

The opening area OA may be located inside the display area DA. In an embodiment, the opening area OA may be arranged at an upper center of the display area DA, as illustrated in FIG. 1. Alternatively, the opening area OA may be arranged in various ways, such as disposed on the upper left side of the display area DA or disposed on the upper right side of the display area DA. FIG. 1 illustrates an example in which one opening area OA is arranged. However, in another embodiment, a plurality of opening areas OA may be provided.

In an embodiment, the opening area OA may be a first area, the display area DA may be a second area, and the intermediate area MA may be a third area.

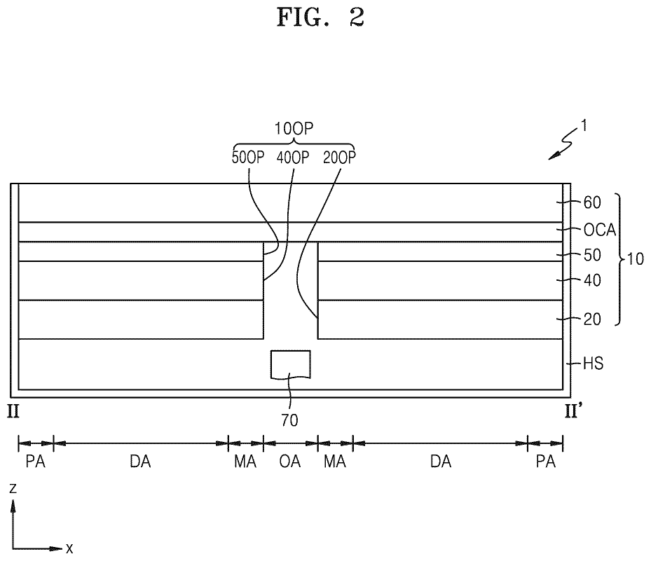

FIG. 2 is a schematic cross-sectional view of an electronic device 1 according to an embodiment, and is a cross-sectional view of the electronic device 1 taken along line II-II′ of FIG. 1.

Referring to FIG. 2, the electronic device 1 may include a display apparatus 10 and a component 70 arranged in an opening area OA of the display apparatus 10. The display apparatus 10 and the component 70 may be accommodated in a housing HS.

The display apparatus 10 may include an image generation layer 20, an input sensing layer 40, an optical function layer 50, and a cover window 60.

The image generation layer 20 may include display elements that emit light to display an image. Each of the display elements may include a light-emitting diode, for example, an organic light-emitting diode including an organic emission layer. In another embodiment, the light-emitting diode may be an inorganic light-emitting diode including an inorganic material. The inorganic light-emitting diode may include a PN junction diode including inorganic semiconductor-based materials. When a voltage is applied in a forward direction to the PN junction diode, holes and electrons may be injected, and energy generated by the recombination of the holes and electrons may be converted into light energy to emit light of a certain color. The inorganic light-emitting diode described above may have a width of several micrometers to several hundred micrometers, or several nanometers to several hundred nanometers. In some embodiments, the image generation layer 20 may include a quantum dot light-emitting diode. For example, the emission layer of the image generation layer 20 may include an organic material, an inorganic material, quantum dots, an organic material and quantum dots, or an inorganic material and quantum dots.

The input sensing layer 40 may obtain coordinate information according to an external input, for example, a touch event (i.e., by a fingertip of a user). The input sensing layer 40 may include a touch electrode (or a sensing electrode) and signal lines (trace lines) connected to the touch electrode. The input sensing layer 40 may be arranged on the image generation layer 20. The input sensing layer 40 may sense an external input by using a mutual capacitance method or/and a self-capacitance method.

The input sensing layer 40 may be formed directly on the image generation layer 20, or may be separately formed and then bonded to the image generation layer 20 through an adhesive layer, such as an optical clear adhesive (OCA). For example, the input sensing layer 40 may be formed continuously after the process of forming the image generation layer 20, and in this case, the adhesive layer may not be disposed between the input sensing layer 40 and the image generation layer 20. Although FIG. 2 illustrates that the input sensing layer 40 is arranged between the image generation layer 20 and the optical function layer 50, in another embodiment, the input sensing layer 40 may be arranged on the optical function layer 50.

The optical function layer 50 may include an anti-reflection layer. The anti-reflection layer may reduce the reflectivity of light (external light) incident from the outside toward the display apparatus 10 through the cover window 60. The anti-reflection layer may include a phase retarder and a polarizer. In another embodiment, the anti-reflection layer may include a black matrix and color filters. The color filters may be arranged by considering the color of light emitted from each of the light-emitting diodes of the image generation layer 20.

In order to improve the transmittance of the opening area OA, the display apparatus 10 may include an opening 10OP passing through some of the layers constituting the display apparatus 10. The opening 10OP may include first to third openings 20OP, 40OP, and 50OP passing through the image generation layer 20, the input sensing layer 40, and the optical function layer 50, respectively. The first opening 20OP of the image generation layer 20, the second opening 40OP of the input sensing layer 40, and the third opening 50OP of the optical function layer 50 may overlap each other or be otherwise aligned in at least one direction to form the opening 10OP of the display apparatus 10.

The cover window 60 may be arranged on the optical function layer 50. The cover window 60 may be bonded to the optical function layer 50 through an adhesive layer, such as an OCA interposed between a lower surface of the cover window 60 and an upper surface of the optical function layer 50. The cover window 60 may cover the first opening 20OP of the image generation layer 20, the second opening 40OP of the input sensing layer 40, and the third opening 50OP of the optical function layer 50.

The cover window 60 may include a glass material or a plastic material. The glass material may include an ultra-thin glass. The plastic material may include one or more of polyethersulfone, polyacrylate, polyether imide, polyethylene naphthalate, polyethylene terephthalate, polyphenylene sulfide, polyarylate, polyimide, polycarbonate, and/or cellulose acetate propionate and/or combinations thereof.

The opening area OA may be a type of component area (e.g., a sensor area, a camera area, or a speaker area) where the component 70 for adding various functions to the electronic device 1 is located.

The component 70 may include an electronic element. For example, the component 70 may be an electronic element that utilizes light or sound. For example, the electronic element may include one or more of a sensor that utilizes light, such as an infrared sensor, a camera that receives light and captures an image, a sensor that outputs and detects light or sound to measure distances or recognize fingerprints, a small lamp that outputs light, and/or a speaker that outputs sound. The electronic element that utilizes light may utilize light of various wavelength bands, such as visible light, infrared light, and ultraviolet light. The opening area OA corresponds to an area through which light or/and sound, which is output to the outside from the component 70 or travels toward the electronic element from the outside, may penetrate.

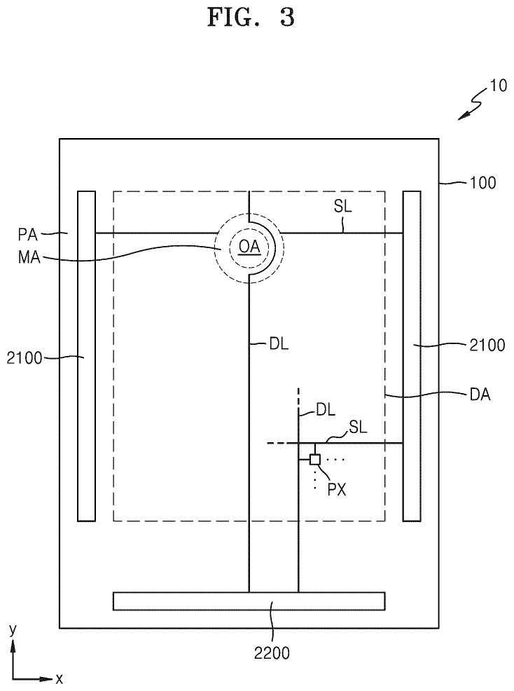

FIG. 3 is a schematic plan view of a display apparatus 10 according to an embodiment.

Referring to FIG. 3, the display apparatus 10 may include a plurality of pixels PX arranged in a display area DA and may display an image by using light emitted from each of the pixels PX. Each pixel PX may emit red, green, or blue light by using a light-emitting diode. The light-emitting diode of each pixel PX may be electrically connected to a scan line SL and a data line DL.

In a peripheral area PA, a scan driver 2100 that provides a scan signal to each pixel PX, a data driver 2200 that provides a data signal to each pixel PX, and a first main power line (not shown) and a second main power line (not shown) for respectively providing a first power voltage (e.g., a driving voltage) and a second power voltage (e.g., a common voltage) may be arranged. Multiple scan drivers 2100 may be arranged on both sides of the display area DA therebetween. In this case, a pixel PX arranged on the left side with respect to the opening area OA may be connected to the scan driver 2100 arranged on the left side, and a pixel PX arranged on the right side with respect to the opening area OA may be connected to the scan driver 2100 arranged on the right side.

The intermediate area MA may surround the opening area OA. The intermediate area MA is an area in which a display element, such as a light-emitting diode, is not arranged, and signal lines providing signals to the pixels PX provided around the opening area OA may pass through the intermediate area MA and around the opening area OA. For example, data lines DL and/or scan lines SL may cross the display area DA, and portions of the data lines DL and/or the scan lines SL may detour in the intermediate area MA along the edge of the opening 10OP of the display apparatus 10 formed in the opening area OA. In an embodiment, FIG. 3 illustrates an example in which the data lines DL cross the display area DA in the y direction and some data lines DL detour to partially surround the opening area OA in the intermediate area MA. The scan lines SL may cross the display area DA in the x direction and may be separated from each other with the opening area OA therebetween.

FIG. 3 illustrates an example in which the data driver 2200 is arranged adjacent to one side of the substrate 100. However, according to another embodiment, the data driver 2200 may be arranged on a printed circuit board electrically connected to a pad arranged on one side of the display apparatus 10. The printed circuit board may be flexible, and a portion of the printed circuit board may be bent to be positioned below the back surface of the substrate 100.

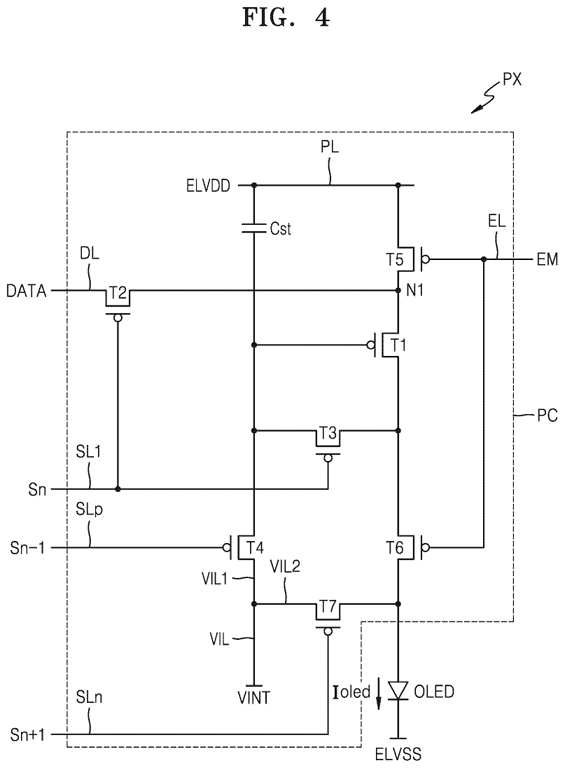

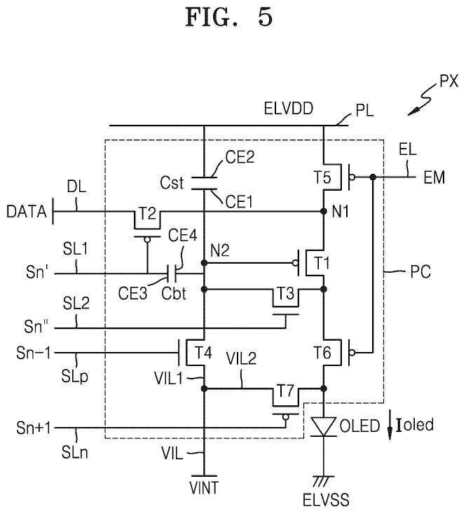

FIGS. 4 and 5 are equivalent circuit diagrams of a pixel PX included in a display apparatus according to embodiments.

Referring to FIG. 4, the pixel PX may include a pixel circuit PC and an organic light-emitting diode OLED that is a display element electrically connected to the pixel circuit PC.

For example, the pixel circuit PC may include a first thin-film transistor T1, a second thin-film transistor T2, a third thin-film transistor T3, a fourth thin-film transistor T4, a fifth thin-film transistor T5, a sixth thin-film transistor T6, a seventh thin-film transistor T7, and a capacitor Cst. However, the disclosure is not limited thereto.

The first thin-film transistor T1 may be a driving transistor, the second thin-film transistor T2 may be a switching transistor, the third thin-film transistor T3 may be a compensation transistor, the fourth thin-film transistor T4 may be a first initialization transistor, the fifth thin-film transistor T5 may be an operation control transistor, the sixth thin-film transistor T6 may be an emission control transistor, and the seventh thin-film transistor T7 may be a second initialization transistor.

The organic light-emitting diode OLED may include a pixel electrode and an opposite electrode, the pixel electrode of the organic light-emitting diode OLED may be connected to the first thin-film transistor T1 via the sixth thin-film transistor T6 to receive a driving current Ioled, and the opposite electrode may receive a common voltage ELVSS. The organic light-emitting diode OLED may generate light having a brightness corresponding to the driving current Ioled.

In an embodiment, the first to seventh thin-film transistors T1 to T7 may all be PMOS transistors. The first to seventh thin-film transistors T1 to T7 may include amorphous silicon or polycrystalline silicon.

The signal lines may include a first scan line SL1, a previous scan line SLp, a subsequent scan line SLn, an emission control line EL, and a data line DL. However, the disclosure is not limited thereto. In addition, the first scan line SL1 may be configured to transmit a first scan signal Sn. The previous scan line SLp may be configured to transmit a previous scan signal Sn-1 to the fourth thin-film transistor T4. The subsequent scan line SLn may be configured to transmit a subsequent scan signal Sn+1 to the seventh thin-film transistor T7. The emission control line EL may be configured to transmit an emission control signal EM to the fifth thin-film transistor T5 and the sixth thin-film transistor T6. The data line DL may be configured to transmit a data signal DATA.

A driving voltage line PL may be configured to transmit a driving voltage ELVDD to the first thin-film transistor T1, and an initialization voltage line VIL may be configured to transmit an initialization voltage VINT to the pixel PX for initializing the first thin-film transistor T1 and the organic light-emitting diode OLED. Specifically, a first initialization voltage line VIL1 may be configured to transmit the initialization voltage VINT to the fourth thin-film transistor T4, and a second initialization voltage line VIL2 may be configured to transmit the initialization voltage VINT to the seventh thin-film transistor T7.

A gate electrode of the first thin-film transistor T1 may be connected to the capacitor Cst, one of a source region and a drain region of the first thin-film transistor T1 may be connected to the driving voltage line PL via the fifth thin-film transistor T5 through a first node N1, and the other of the source region and the drain region of the first thin-film transistor T1 may be electrically connected to the pixel electrode of the organic light-emitting diode OLED via the sixth thin-film transistor T6. The first thin-film transistor T1 may be configured to receive the data signal DATA according to a switching operation of the second thin-film transistor T2 and may supply the driving current Ioled to the organic light-emitting diode OLED.

A gate electrode of the second thin-film transistor T2 may be connected to the first scan line SL1 configured to transmit the first scan signal Sn, one of a source region and a drain region of the second thin-film transistor T2 may be connected to the data line DL, and the other of the source region and the drain region of the second thin-film transistor T2 may be connected to the first thin-film transistor T1 through the first node N1 and may be connected to the driving voltage line PL via the fifth thin-film transistor T5. The second thin-film transistor T2 may be configured to be turned on according to the first scan signal Sn received through the first scan line SL1 and transfer the data signal DATA, which is transmitted through the data line DL, to the first thin-film transistor T1 through the first node N1.

A gate electrode of the third thin-film transistor T3 may be connected to the first scan line SL1. One of a source region and a drain region of the third thin-film transistor T3 may be connected to the pixel electrode of the organic light-emitting diode OLED via the sixth thin-film transistor T6. The other of the source region and the drain region of the third thin-film transistor T3 may be connected to the capacitor Cst and the gate electrode of the first thin-film transistor T1. The third thin-film transistor T3 may be configured to be turned on according to the first scan signal Sn received through the first scan line SL1 and may diode-connect the first thin-film transistor T1.

A gate electrode of the fourth thin-film transistor T4 may be connected to the previous scan line SLp. One of a source region and a drain region of the fourth thin-film transistor T4 may be connected to the first initialization voltage line VIL1. The other of the source region and the drain region of the fourth thin-film transistor T4 may be connected to a first capacitor electrode CE1 of the capacitor Cst and the gate electrode of the first thin-film transistor T1. The fourth thin-film transistor T4 may be configured to be turned on according to the previous scan signal Sn-1 received through the previous scan line SLp and may transfer the initialization voltage VINT to the gate electrode of the first thin-film transistor T1 to initialize the voltage of the gate electrode of the first thin-film transistor T1.

A gate electrode of the fifth thin-film transistor T5 may be connected to the emission control line EL, one of a source region and a drain region of the fifth thin-film transistor T5 may be connected to the driving voltage line PL, and the other may be connected to the first thin-film transistor T1 and the second thin-film transistor T2 through the first node N1.

A gate electrode of the sixth thin-film transistor T6 may be connected to the emission control line EL, one of a source region and a drain region of the sixth thin-film transistor T6 may be connected to the first thin-film transistor T1 and the third thin-film transistor T3, and the other of the source region and the drain region of the sixth thin-film transistor T6 may be electrically connected to the pixel electrode of the organic light-emitting diode OLED.

The fifth thin-film transistor T5 and the sixth thin-film transistor T6 may be simultaneously turned on according to the emission control signal EM received through the emission control line EL, and thus, the driving voltage ELVDD may be transferred to the organic light-emitting diode OLED to allow the driving current Ioled to flow through the organic light-emitting diode OLED.

A gate electrode of the seventh transistor T7 may be connected to the subsequent scan line SLn, one of a source region and a drain region of the seventh transistor T7 may be connected to the pixel electrode of the organic light-emitting diode OLED, and the other of the source region and the drain region of the seventh transistor T7 may be connected to the second initialization voltage line VIL2 to receive the initialization voltage VINT. Th seventh transistor T7 may be configured to be turned on according to the subsequent scan signal Sn+1 received through the subsequent scan line SLn and may initialize the pixel electrode of the organic light-emitting diode OLED. The subsequent scan line SLn may be the same as the first scan line SL1. In this case, the relevant scan line may be configured to transmit the same electric signal with a time difference, and thus, may function as the first scan line SL1 and as the subsequent scan line SLn. In some embodiments, the seventh transistor T7 may be omitted.

The capacitor Cst may be connected to the driving voltage line PL and the gate electrode of the first thin-film transistor T1 and store and maintain a voltage corresponding to a voltage difference between both ends of the capacitor Cst, thereby maintaining a voltage applied to the gate electrode of the first thin-film transistor T.

Detailed operations of the pixel circuit PC and the organic light-emitting diode OLED, which is a display element, according to an embodiment are described below.

During an initialization period, when a previous scan signal Sn-1 is supplied through the previous scan line SLp, the fourth thin-film transistor T4 is turned on according to the previous scan signal Sn-1, and the first thin-film transistor T1 may be initialized by the initialization voltage VINT supplied from the first initialization voltage line VIL1.

During a data programming period, when a first scan signal Sn is supplied through the first scan line SL1, the second thin-film transistor T2 and the third thin-film transistor T3 may be turned on in response to the first scan signal Sn. In this case, the first thin-film transistor T1 may be diode-connected and forward-biased by the third thin-film transistor T3 that is turned on. Then, a compensation voltage (DATA+Vth (Vth has a (−) value)) may be applied to the gate electrode of the first thin-film transistor T1, wherein the compensation voltage (DATA+Vth) is obtained by subtracting a threshold voltage Vth of the first thin-film transistor T1 from a data signal DATA supplied from the data line DL. The driving voltage ELVDD and the compensation voltage (DATA+Vth) are respectively applied to two opposite ends of the capacitor Cst, and charge corresponding to a difference between voltages of the two opposite ends may be stored in the capacitor Cst.

During an emission period, the fifth thin-film transistor T5 and the sixth thin-film transistor T6 may be turned on according to an emission control signal En supplied from the emission control line EL. The driving current Ioled corresponding to a voltage difference between the voltage of the gate electrode of the first thin-film transistor T1 and the driving voltage ELVDD may be generated, and the driving current Ioled may be supplied to the organic light-emitting diode OLED through the sixth thin-film transistor T6.

Referring to FIG. 5, a pixel circuit PC of the pixel PX may include first to seventh thin-film transistors T1-T7, a first capacitor Cst, a second capacitor Cbt, and an organic light-emitting diode OLED that is a display element.

Some of the first to seventh thin-film transistors T1 to T7 may be n-channel MOSFET (NMOS) transistors, and others may be p-channel MOSFET (PMOS) transistors. For example, as illustrated in FIG. 5, among the first to seventh thin-film transistors T1 to T7, the third thin-film transistor T3 and the fourth thin-film transistor T4 may be NMOS transistors, and the rest may be PMOS transistors. Alternatively, among the first to seventh thin-film transistors T1 to T7, the third thin-film transistor T3, the fourth thin-film transistor T4, and the seventh transistor T7 may be NMOS transistors, and the rest may be PMOS transistors. Alternatively, all of the first to seventh thin-film transistors T1 to T7 may be NMOS transistors.

Signal lines may include a first scan line SL1 configured to transmit a first scan signal Sn′, a second scan line SL2 configured to transmit a second scan signal Sn″, a previous scan line SLp configured to transmit a previous scan signal Sn-1 to the fourth thin-film transistor T4, an emission control line EL configured to transmit an emission control signal EM to the fifth thin-film transistor T5 and the sixth thin-film transistor T6, a subsequent scan line SLn configured to transmit a subsequent scan signal Sn+1 to the seventh transistor T7, and a data line DL configured to transmit a data signal DATA.

The first thin-film transistor T1 may be connected to a driving voltage line PL via the fifth thin-film transistor T5 and may be electrically connected to the organic light-emitting diode OLED via the sixth thin-film transistor T6. The first thin-film transistor T1 may be configured to receive the data signal DATA according to a switching operation of a second thin-film transistor T2 and may supply a driving current Ioled to the organic light-emitting diode OLED.

The second thin-film transistor T2 may be connected to the first scan line SL1 and the data line DL and may be connected to the driving voltage line PL via the fifth thin-film transistor T5. The second thin-film transistor T2 may be configured to be turned on according to the first scan signal Sn′ received through the first scan line SL1 and may transfer the data signal DATA, which is transmitted through the data line DL, to the first node N1.

The third thin-film transistor T3 may be connected to the second scan line SL2 and may be connected to the organic light-emitting diode OLED via the sixth thin-film transistor T6. The third thin-film transistor T3 may be configured to be turned on according to the second scan signal Sn″ received through the second scan line SL2 and may diode-connect the first thin-film transistor T1 to thereby compensate the threshold voltage of the first thin-film transistor T1.

The fourth thin-film transistor T4 may be connected to the previous scan line SLp and the first initialization voltage line VIL1, and may be configured to be turned on according to the previous scan signal Sn-1 received through the previous scan line SLp and may transfer the initialization voltage VINT from the first initialization voltage line VIL1 to a gate electrode of the first thin-film transistor T1 to initialize the voltage of the gate electrode of the first thin-film transistor T1.

The fifth thin-film transistor T5 and the sixth thin-film transistor T6 may be connected to the emission control line EL, and may be configured to be simultaneously turned on according to the emission control signal EM received through the emission control line EL and may form a current path so that a driving current I_{OLED} may flow from the driving voltage line PL to the organic light-emitting diode OLED.

The seventh transistor T7 may be connected to the subsequent scan line SLn and the second initialization voltage line VIL2, and may be configured to be turned on according to the subsequent scan signal Sn+1 received through the subsequent scan line SLn and may transfer the initialization voltage VINT from the second initialization voltage line VIL2 to the organic light-emitting diode OLED to initialize the organic light-emitting diode OLED. The seventh transistor T7 may be omitted.

The first capacitor Cst may include a first capacitor electrode CE1 and a second capacitor electrode CE2. The first capacitor electrode CE1 may be connected to the gate electrode of the first thin-film transistor T1, and the second capacitor electrode CE2 may be connected to the driving voltage line PL. The first capacitor Cst may maintain a voltage applied to the gate electrode of the first thin-film transistor T1 by storing and maintaining a voltage corresponding to a voltage difference between the driving voltage line PL and the gate electrode of the first thin-film transistor T1.

The second capacitor Cbt may include a third capacitor electrode CE3 and a fourth capacitor electrode CE4. The third capacitor electrode CE3 may be connected to the first scan line SL1 and a gate electrode of the second thin-film transistor T2. The fourth capacitor electrode CE4 may be connected to the gate electrode of the first thin-film transistor T1 and the first capacitor electrode CE1 of the first capacitor Cst. The second capacitor Cbt may be a boosting capacitor, and when the first scan signal Sn of the first scan line SL1 has a voltage for turning off the second thin-film transistor T2, the second capacitor Cbt may increase the voltage of the second node N2 to clearly express a black gradation.

In an embodiment, at least one of the first to seventh transistors T1 to T7 may include a semiconductor layer including oxide, and the rest may include a semiconductor layer including amorphous silicon or polycrystalline silicon.

Specifically, the first thin-film transistor that is a driving transistor directly affecting the brightness of the display apparatus 10 may include a semiconductor layer including polycrystalline silicon having high reliability, thereby realizing a high-resolution display apparatus.

Because an oxide semiconductor has high carrier mobility and low leakage current, a voltage drop may not be large even though a driving time is long. That is, because a color change of an image according to a voltage drop is not large even during low-frequency driving, low-frequency driving may be possible.

As described above, because an oxide semiconductor has an advantage of a small leakage current, at least one of the third thin-film transistor T3 and the fourth thin-film transistor T4 connected to the gate electrode of the first thin-film transistor T1 may employ an oxide semiconductor to thereby prevent leakage current flowing to the gate electrode of the first thin-film transistor T1 and reduce power consumption.

The pixel circuit PC is not limited to the number and circuit design of thin-film transistors and capacitors described with reference to FIGS. 4 and 5, and the number and circuit design may be variously changed.

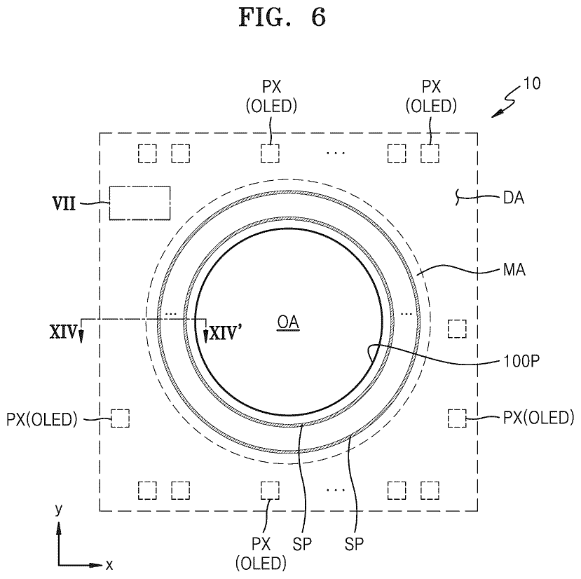

FIG. 6 is a plan view of a portion of a display apparatus 10 according to an embodiment.

FIG. 6 shows an opening area OA, an intermediate area MA, and a display area DA of the display apparatus 10. Pixels PX may be arranged in the display area DA. The pixels PX may be arranged to surround the opening area OA and the intermediate area MA in the display area DA. Each of the pixels PX corresponds to a minimum area through which light is emitted, and light may be emitted through a display element, such as a light-emitting diode. The position of the pixel PX may correspond to the position of the light-emitting diode. The fact that the pixel PX is arranged in the display area DA may indicate that the light-emitting diode is arranged in the display area DA.

Pixels PX and/or light-emitting diodes adjacent to the opening area OA may be arranged to be separated from each other around the opening area OA in a plan view. The pixels PX and/or the light-emitting diodes may be arranged to be separated from each other vertically around or at vertically opposite sides of the opening area OA, or to be separated from each other in left and right directions around or at left-right opposite sides of the opening area OA.

Separators SP may be arranged to be separated from each other in the intermediate area Ma in, for example, a radial dimension. In other words, the separators SP may be arranged to be separated from each other between the display area DA and the opening area OA, or between the display area DA and the opening 10OP. Each of the separators SP may have a closed loop shape in a plan view (e.g., when viewed in a direction perpendicular to the upper surface of a substrate).

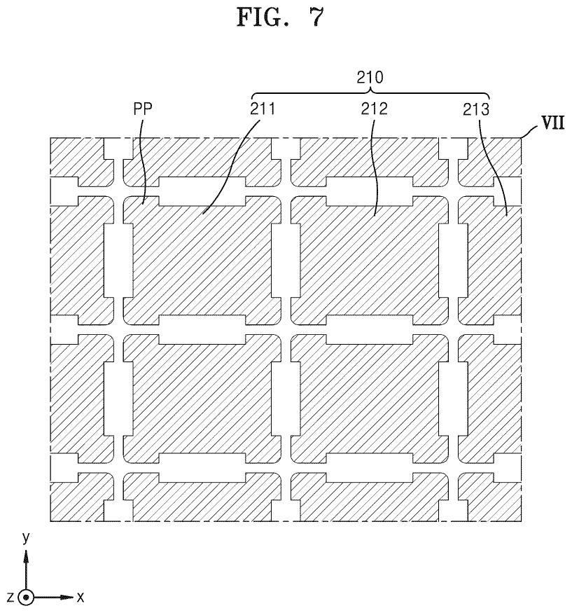

FIGS. 7 to 10 are schematic enlarged plan views of a portion of a display apparatus according to an embodiment, and illustrate an area VII of FIG. 6. That is, FIGS. 7 to 10 are schematic plan views of a portion of the display area DA of the display apparatus 10.

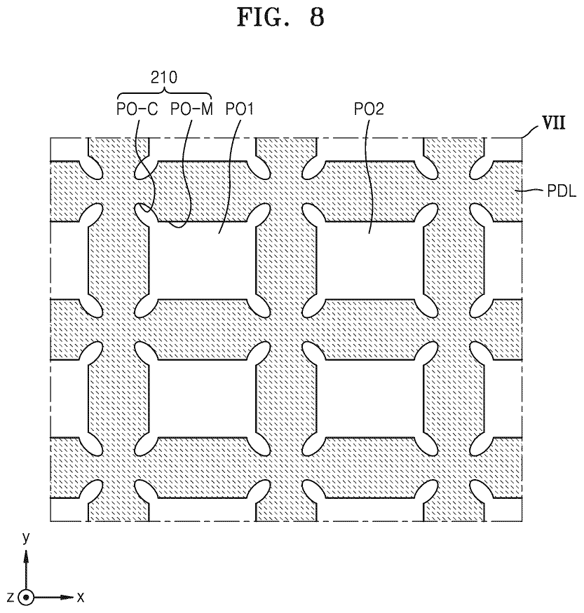

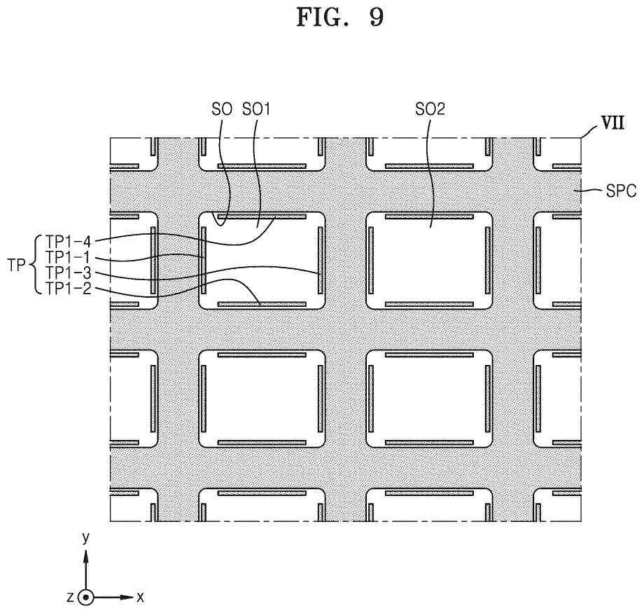

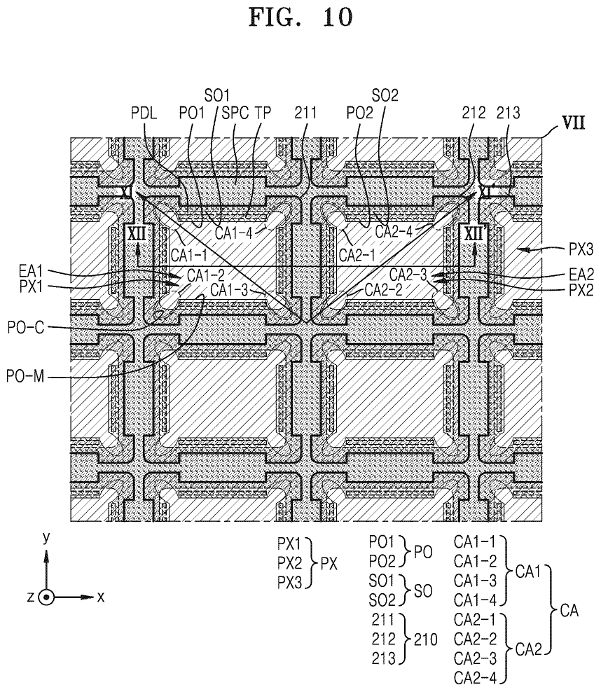

Specifically, FIG. 7 is a plan view showing the arrangement of pixel electrodes 210, FIG. 8 is a plan view showing the arrangement of pixel-defining layer(s) PDL, FIG. 9 is a plan view showing the arrangement of spacer(s) SPC, and FIG. 10 is a plan view showing the arrangement of the pixel electrodes 210, the pixel-defining layer(s) PDL, and the spacer(s) SPC.

Referring to FIGS. 7 to 10, a plurality of pixels PX may be arranged on a substrate 100 of the display area DA. Each of the pixels PX may refer to a sub-pixel and may include a display element, such as the organic light-emitting diode OLED. The pixel PX may emit, for example, green light, red light, or blue light. For example, the pixel PX may be a first pixel PX1 emitting green light, a second pixel PX2 emitting red light, or a third pixel PX3 emitting blue light. The green light may be light belonging to a wavelength band of about 495 nm to about 580 nm, the red light may be light belonging to a wavelength band of about 580 nm to about 780 nm, and the blue light may be light belonging to a wavelength band of about 400 nm to about 495 nm.

In particular, referring to FIG. 7, a plurality of pixel electrodes 210 may be arranged in the display area DA. The plurality of pixel electrodes 210 may include a first pixel electrode 211 included in the first pixel PX1, a second pixel electrode 212 included in the second pixel PX2, and a third pixel electrode 213 included in the third pixel PX3. For example, the first pixel electrode 211, the second pixel electrode 212, and the third pixel electrode 213 may be arranged to be separated from each other in a plan view. The first pixel electrode 211, the second pixel electrode 212, and the third pixel electrode 213 may have the same size, as illustrated in FIG. 7. In another embodiment, the first pixel electrode 211, the second pixel electrode 212, and the third pixel electrode 213 may have different sizes. For simplicity, the third pixel PX3 will not be described below.

In an embodiment, the pixel electrode 210 may have a polygonal shape. For example, the pixel electrode 210 may have an approximately quadrangular shape, as illustrated in FIG. 7. In this case, in an embodiment, the pixel electrode 210 may have a protrusion PP. The protrusion PP may be a portion that protrudes outward from a portion of the perimeter of the pixel electrode 210. In an embodiment, the protrusion PP may protrude from a point where the edges of the pixel electrodes 210 meet, for example, from a portion corresponding to a corner of a polygon. In addition, the pixel electrode 210 may be larger than a pixel opening PO and a spacer opening SO, which are described below.

The display apparatus 10 may define a pixel area including an emission area EA and a connection area CA (see FIG. 10). Accordingly, the pixel area including the emission area EA and the connection area CA may also be defined on the pixel electrode 210. The emission area EA is an area where light is emitted and may be an area corresponding to a central portion of the pixel electrode 210. The connection area CA may be located at the edge of the emission area EA. At least one connection area CA may be provided in one pixel. For example, when the emission area EA has an approximately polygonal shape, the connection area CA may be located at the corners of the emission area EA. The connection area CA may partially overlap the emission area EA.

Referring to FIG. 8, the pixel-defining layer PDL may be arranged on the pixel electrode 210 and may include a pixel opening PO that exposes at least a portion of the pixel electrode 210. The pixel opening PO may expose a central portion of the pixel electrode 210. In an embodiment, the pixel opening PO may include a first main opening PO-M corresponding to the emission area EA and a connection opening PO-C corresponding to the connection area CA. The first main opening PO-M may have a polygonal shape corresponding to the emission area EA. The connection opening PO-C may have a shape that protrudes outward from a corner of the polygonal shape. For example, when the emission area EA has a quadrangular shape, the first main opening PO-M may have a quadrangular shape to expose the pixel electrode 210, and the connection opening PO-C may be formed to extend at positions corresponding to the four corners of the quadrangular shape.

The pixel opening PO may include a first pixel opening PO1 arranged on the first pixel electrode 211 and a second pixel opening PO2 arranged on the second pixel electrode 212. In an embodiment, the first pixel opening PO1 may be arranged to correspond to the first emission area EA1 and the first connection area CA1 (see FIG. 10). The second pixel opening PO2 may be arranged to correspond to the second emission area EA2 and the second connection area CA2.

As shown in FIG. 10, a plurality of first connection areas CA1 and a plurality of second connection areas CA2 may be provided. For example, the first connection area CA1 may include a first-1 connection area CA1-1, a first-2 connection area CA1-2, a first-3 connection area CA1-3, and a first-4 connection area CA1-4. Similarly, the second connection area CA2 may include a second-1 connection area CA2-1, a second-2 connection area CA2-2, a second-3 connection area CA2-3, and a second-4 connection area CA2-4.

The first pixel opening PO1 and the second pixel opening PO2 may have the same size, as illustrated in FIG. 8. In another embodiment, the first pixel opening PO1 and the second pixel opening PO2 may have different sizes.

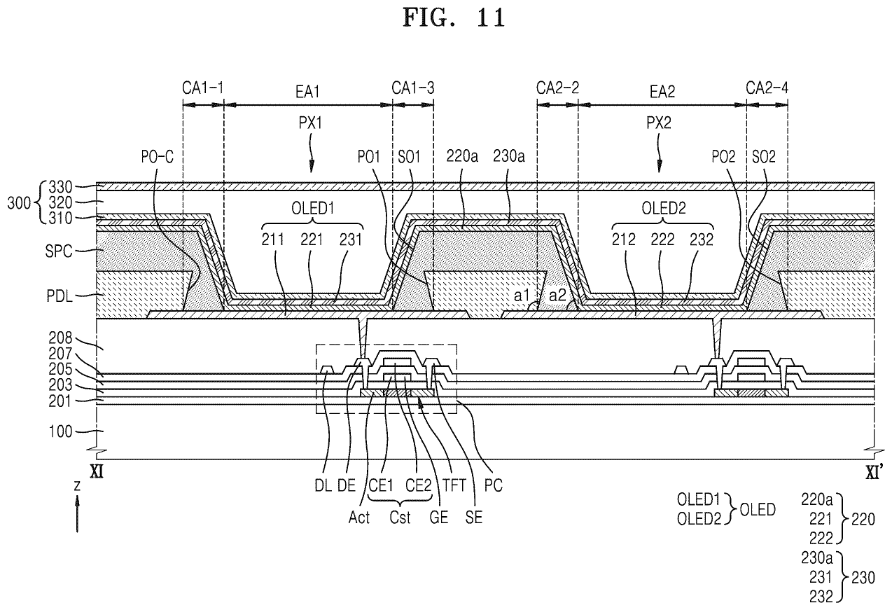

Although not shown in FIGS. 7 to 10, an emission layer (not shown) that emits light may be located within the pixel opening PO of the pixel-defining layer PDL. An opposite electrode 230 (see FIG. 11) may be arranged on the emission layer. A stacked structure of the pixel electrode 210, the emission layer, and the opposite electrode 230 may form one organic light-emitting diode OLED. One opening of the pixel-defining layer PDL may correspond to one organic light-emitting diode OLED.

Referring to FIG. 9, a spacer SPC may be arranged on the pixel-defining layer PDL. The spacer SPC may include a spacer opening SO that exposes at least a portion of the pixel electrode 210. The spacer opening SO may expose a central portion of the pixel electrode 210.

In an embodiment, the spacer opening SO may be arranged to overlap the pixel opening PO. In an embodiment, in a plan view, the spacer opening SO may be formed to be larger than the perimeter of a portion of the pixel opening PO and smaller than the perimeter of another portion of the pixel opening PO. That is, in the emission area EA, the spacer opening SO may be larger than the pixel opening PO, and in the connection area CA, the spacer opening SO may be smaller than the pixel opening PO. Specifically, in a plan view, the perimeter of the spacer opening SO may be arranged outside the perimeter of the first main opening PO-M of the pixel opening PO. In this case, the “outside” may mean a direction away from the center of a pixel. That is, the spacer opening S0 may be larger than the first main opening PO-M of the pixel opening PO. In addition, in a plan view, the perimeter of the spacer opening SO may be arranged inside the perimeter of the connection opening PO-C of the pixel opening PO. In this case, the “inside” may mean a direction toward the center of the pixel. That is, in a plan view, the perimeter of the spacer opening SO may cross the connection opening PO-C.

In other words, a portion of the spacer SPC may be arranged inside the connection opening PO-C. In addition, a portion of the spacer SPC may be arranged to overlap the connection area CA. The spacer SPC may not be arranged in the emission area EA, and a portion of the spacer SPC may be arranged in the connection area CA.

As illustrated in FIG. 9, the spacer opening SO may have a polygonal shape such as or including a quadrangle in a plan view. In another embodiment, the spacer opening SO may have one of a circular shape and an annular shape or may have an irregular shape.

The spacer opening SO may include a first spacer opening SO1 arranged on the first pixel electrode 211 and a second spacer opening SO2 arranged on the second pixel electrode 212. The first spacer opening SO1 and the second spacer opening SO2 may have the same size, as illustrated in FIG. 9. In another embodiment, the first spacer opening SO1 and the second spacer opening SO2 may have different sizes.

A second angle a2 formed between the inner surface of the spacer SPC defining the spacer opening SO and the substrate 100 (see FIG. 11) may be less than a first angle a1 formed between the inner surface of the pixel-defining layer PDL defining the pixel opening PO and the substrate 100 (see FIG. 11). Specific details will be described below through a cross-sectional view.

In an embodiment, the spacer SPC may include a tail portion TP. The tail portion TP may be a portion of the spacer SPC arranged within the spacer opening SO. In an embodiment, the tail portion TP may be separated inwardly from an edge of the spacer opening SO and may extend along the edge of the spacer opening SO.

In addition, in an embodiment, a plurality of tail portions TP may be provided, and the plurality of tail portions TP may be separated inwardly from each of the peripheral edges of the spacer opening SO and may each extend along the edge of the spacer opening SO. In this case, the plurality of tail portions TP may be separated from each other without being connected to each other. That is, for example, four tail portions TP may be arranged in the spacer opening SO having a quadrangular shape, and the four tail portions TP may be separated from each other without being connected to each other at the corners of the spacer opening SO.

Four tail portions TP of the first spacer opening SO1 may be defined as a first-1 tail portion TP1-1, a first-2 tail portion TP1-2, a first-3 tail portion TP1-3, and a first-4 tail portion TP1-4, respectively. Similarly, four tail portions TP of the second spacer opening SO-2 may be defined as a second-1 tail portion TP2-1, a second-2 tail portion TP2-2, a second-3 tail portion TP2-3, and a second-4 tail portion TP2-4, respectively.

In an embodiment, each of the tail portions TP may be arranged to overlap the pixel-defining layer PDL in a plan view. In other words, the tail portion TP may be arranged between the perimeter of the pixel opening PO and the perimeter of the spacer opening SO.

FIG. 11 is a schematic cross-sectional view of the display apparatus 10 taken along line XI-XI′ of FIG. 10.

As illustrated in FIG. 11, the display apparatus 10 according to the present embodiment may include a substrate 100. The substrate 100 may include various materials that are flexible or bendable. For example, the substrate 100 may include one or more of glass, metal, and/or polymer resin. In addition, the substrate 100 may include one or more of a polymer resin, such as polyethersulphone, polyacrylate, polyetherimide, polyethylene naphthalate, polyethylene terephthalate, polyphenylene sulfide, polyarylate, polyimide, polycarbonate, and/or cellulose acetate propionate. The substrate 100 may have various modifications, such as a multi-layer structure including two layers each including the polymer resin and a barrier layer including an inorganic material (such as one or more of silicon oxide, silicon nitride, and/or silicon oxynitride) between the two layers.

On the substrate 100, the pixels PX each including a display element and a pixel circuit PC may be arranged. In FIG. 4, each of the pixels PX is illustrated as including an organic light-emitting diode OLED as the display element. For example, the organic light-emitting diode OLED may be a first organic light-emitting diode OLED1 or a second organic light-emitting diodes OLED2. That is, the first pixel PX1 may include the first organic light-emitting diode OLED1, and the second pixel PX2 may include the second organic light-emitting diode OLED2.

The pixel circuit PC may be arranged on the substrate 100. Because the structures of the pixel circuits PC of the pixels PX are the same, the description will focus on one pixel circuit PC. The pixel circuit PC includes a plurality of thin-film transistors TFT and a storage capacitor Cst. For convenience of illustration, one thin-film transistor TFT is illustrated in FIG. 11, and the thin-film transistor TFT may correspond to the driving transistor T1 (see FIG. 4) described above.

A buffer layer 201 including an inorganic material, such as one or more of silicon oxide, silicon nitride, and/or silicon oxynitride, may be arranged between the thin-film transistor TFT and the substrate 100. The buffer layer 201 may increase the smoothness of an upper surface of the substrate 100 or prevent or reduce impurities from the substrate 100 or the like from penetrating into a semiconductor layer Act of the thin-film transistor TFT.

As illustrated in FIG. 11, the thin-film transistor TFT may have the semiconductor layer Act including one or more of amorphous silicon, polycrystalline silicon, an organic semiconductor material, and/or an oxide semiconductor material. In addition, the thin-film transistor TFT may include a gate electrode GE, a source electrode SE, and/or a drain electrode DE. The gate electrode GE may include various conductive materials and may have various layered structures. For example, the gate electrode GE may include one of a Mo layer and an Al layer. Alternatively, the gate electrode GE may include one of a TiNx layer, an Al layer, and/or a Ti layer. Each of the source electrode SE and the drain electrode DE may also include various conductive materials and may have various layered structures. For example, each of the source electrode SE and the drain electrode DE may include one of more of a Ti layer, an Al layer, and/or a Cu layer.

In order to secure insulation between the semiconductor layer Act and the gate electrode GE, a gate insulating layer 203 including an inorganic material, such as one or more of silicon oxide, silicon nitride, and/or silicon oxynitride, may be arranged between the semiconductor layer Act and the gate electrode GE. In FIG. 11, the gate insulating layer 203 is illustrated as having a shape corresponding to the entire surface of the substrate 100 and having a structure in which contact holes are formed in preset portions, but the disclosure is not limited thereto. For example, the gate insulating layer 203 may be patterned to have the same shape as the gate electrode GE.

In addition, a first interlayer insulating layer 205 including an inorganic material, such as one or more of silicon oxide, silicon nitride, and/or silicon oxynitride, may be arranged on the gate electrode GE. The first interlayer insulating layer 205 may have a single-layer or multi-layer structure including the aforementioned material. An insulating layer including the inorganic material may be formed through chemical vapor deposition (CVD) or atomic layer deposition (ALD). The same applies to embodiments to be described below and modifications thereof.

The storage capacitor Cst may include a first capacitor electrode CE1 and a second capacitor electrode CE2 that overlap each other with the first interlayer insulating layer 205 therebetween. The storage capacitor Cst may overlap the thin-film transistor TFT. In this regard, FIG. 11 illustrates that the gate electrode GE of the thin-film transistor TFT is the first capacitor electrode CE1 of the storage capacitor Cst. However, the disclosure is not limited thereto. For example, the storage capacitor Cst may not overlap the thin-film transistor TFT. The second capacitor electrode CE2 of the storage capacitor Cst may include a conductive material including one or more of molybdenum (Mo), aluminum (Al), copper (Cu), titanium (Ti), and/or the like, and may have a multi-layer or single-layer structure including the conductive material.

A second interlayer insulating layer 207 including an inorganic material, such as one or more of silicon oxide, silicon nitride, and/or silicon oxynitride, may be arranged on the second capacitor electrode CE2 of the storage capacitor Cst. The second interlayer insulating layer 207 may have a single-layer or multi-layer structure including the aforementioned material.

The source electrode SE and the drain electrode DE may be arranged on the second interlayer insulating layer 207. A data line DL may be located on the same layer as the source electrode SE and the drain electrode DE and may include the same material as the source electrode SE and the drain electrode DE. The source electrode SE, the drain electrode DE, and the data line DL may each include a material having excellent conductivity. The source electrode SE and the drain electrode DE may each include a conductive material such as one or more of molybdenum (Mo), aluminum (Al), copper (Cu), titanium (Ti), and/or the like and may have a multi-layer or single-layer structure including the conductive material. For example, the source electrode SE, the drain electrode DE, and the data line DL may each have a multi-layer structure including Ti/Al/Ti layers.

However, the disclosure is not limited thereto. For example, the thin-film transistor TFT may have only one of the source electrode SE and the drain electrode DE, or may not have both of them. For example, one thin-film transistor TFT may not have a drain electrode DE and another thin-film transistor TFT connected to one thin-film transistor TFT may not have a source electrode SE, and the semiconductor layers Act of these two thin-film transistors TFT may be connected to each other. This connection structure may have the same effect as when one thin-film transistor TFT has a source electrode SE and another thin-film transistor TFT has a drain electrode DE, and the source electrode SE of one thin-film transistor TFT is connected to the drain electrode DE of the other thin-film transistor TFT.

As illustrated in FIG. 11, a planarization layer 208 may be arranged to cover the thin-film transistor TFT and the storage capacitor Cst. The planarization layer 208 may include an organic insulating material. For example, the planarization layer 208 may include one or more of photoresist, benzocyclobutene (BCB), polyimide, hexamethyldisiloxane (HMDSO), polymethylmethacrylate (PMMA), polystyrene, a polymer derivative having a phenol group, an acrylic polymer, an imide polymer, an aryl ether polymer, an amide polymer, a fluorinated polymer, a p-xylene polymer, a vinyl alcohol polymer, and/or a mixture thereof. Although not shown in FIG. 11, a third interlayer insulating layer (not shown) may be further arranged under the planarization layer 208. The third interlayer insulating layer may include one or more of an inorganic insulating material, such as silicon oxide, silicon nitride, and/or silicon oxynitride.

On the planarization layer 208, the first organic light-emitting diode OLED1 and the second organic light-emitting diode OLED2 may be arranged to be separated from each other.

The first pixel electrode 211 and the second pixel electrode 212 may be arranged to be separated from each other on the planarization layer 208. The first pixel electrode 211 and the second pixel electrode 212 may each include a light-transmitting conductive layer including a light-transmitting conductive oxide, such as one or more of ITO, In₂O₃, and/or IZO, and a reflective layer including a metal, such as Al or Ag. For example, the first pixel electrode 211 and the second pixel electrode 212 may each have a three-layer structure including ITO/Ag/ITO layers.

The first pixel electrode 211 and the second pixel electrode 212 may be electrically connected to the thin-film transistor TFT by contacting one of the source electrode SE and the drain electrode DE, as illustrated in FIG. 11. Specifically, each of the first pixel electrode 211 and the second pixel electrode 212 may be in contact with one of the source electrode SE and the drain electrode DE through a contact hole formed in the planarization layer 208.

A pixel-defining layer PDL may be arranged on the planarization layer 208. The pixel-defining layer PDL has a pixel opening PO that exposes at least a portion of the pixel electrode 210, thereby defining a pixel PX.

The pixel-defining layer PDL may include the pixel opening PO. The pixel opening PO may include a first pixel opening PO1 arranged on the first pixel electrode 211 and a second pixel opening PO2 arranged on the second pixel electrode 212. In an embodiment, the first pixel opening PO1 may be arranged to correspond to the first emission area EA1 and the first connection area CA1. The second pixel opening PO2 may be arranged to correspond to the second emission area EA2 and the second connection area CA2.

The first connection area CA1 and the second connection area CA2 may be located at the edge of the pixel opening PO. A plurality of first connection areas CA1 and a plurality of second connection areas CA2 may be provided. For example, the first connection area CA1 may include a first-1 connection area CA1-1 and a first-3 connection area CA1-3. The second connection area CA2 may include a second-2 connection area CA2 -2 and a second-4 connection area CA2-4. FIG. 11 shows cross-sections of the first-1 connection area CA1-1, the first-3 connection area CA1-3, the second-2 connection area CA2-2, and the second-4 connection area CA2-4, i.e., cross-sections crossing the corners of the pixels PX.

The pixel-defining layer PDL may increase the distance between the edge of the pixel electrode 210 and the opposite electrode 230 above the pixel electrode 210. As a result, occurrence of an arc or the like at the edge of the pixel electrode 210 may be prevented. The pixel-defining layer PDL may include an organic material, such as one or more of polyimide and/or HMDSO. In some embodiments, the pixel-defining layer PDL may include a light-blocking material and may be formed in black. The light-blocking material may include one or more of carbon black, carbon nanotubes, a resin or paste containing black dye, metal particles (e.g., nickel, aluminum, molybdenum, or an alloy thereof), metal oxide particles (e.g., chromium oxide), and/or metal nitride particles (e.g., chromium nitride). When the pixel-defining layer PDL includes the light-blocking material, external light reflection by metal structures arranged under the pixel-defining layer PDL may be reduced.

Referring to FIG. 11, in an embodiment, the pixel-defining layer PDL may be provided in a reverse shape in the connection area CA. That is, the first angle a1 formed between the inner surface of the pixel-defining layer PDL defining the pixel opening PO and the upper surface of the substrate 100 may have a range of 90° or more and 170° or less. The pixel-defining layer PDL may be tapered toward the emission area EA as a distance increases upward from the substrate.

A spacer SPC may be arranged on the pixel-defining layer PDL. The spacer SPC may include a spacer opening SO exposing at least a portion of the pixel electrode 210. The spacer opening SO may include a first spacer opening SO1 exposing at least a portion of the first pixel electrode 211 and a second spacer opening SO2 exposing at least a portion of the second pixel electrode 212.

A portion of the spacer SPC may be arranged inside the pixel opening PO of the pixel-defining layer PDL. The spacer SPC may be arranged in a connection opening PO-C included in the pixel opening PO. The interior of the pixel opening PO where the spacer SPC is arranged may overlap the connection area CA. Referring to FIG. 11, a portion of the spacer SPC may be arranged in the first-1 connection area CA1-1, the first-3 connection area CA1-3, the second-2 connection area CA2-2, and the second-4 connection area CA2-4.

In an embodiment, the spacer SPC may include a different material from the pixel-defining layer PDL. For example, the pixel-defining layer PDL may include a negative photosensitive material, while the spacer SPC may include a positive photosensitive material. That is, the pixel-defining layer PDL and the spacer SPC may include different materials and may be formed through separate mask processes.

Specifically, an organic material including a negative photosensitive material may be applied onto the planarization layer 208, and then an area excluding the pixel opening PO may be exposed. Because the organic material includes a negative photosensitive material, an area corresponding to the pixel opening PO, which is not exposed, may be developed and removed, and the area excluding the pixel opening PO, which is exposed, may be hardened to form the pixel-defining layer PDL. In this case, because the exposure amount of an upper portion of the organic material is relatively greater and the exposure amount of a lower portion of the organic material is relatively less, the pixel-defining layer PDL may be formed to have a reverse shape structure, as illustrated in FIG. 11.

Next, an organic material including a positive photosensitive material is applied onto the pixel-defining layer PDL, and then an area corresponding to the spacer opening SO may be exposed. Because the organic material includes a positive photosensitive material, the area corresponding to the spacer opening SO, which is exposed, may be developed and removed. In this case, because the exposure amount of an upper portion of the organic material is relatively greater, the upper portion of the spacer opening SO is more removed, and the spacer SPC may be formed to have a normal shape structure, as illustrated in FIG. 11.

In the connection area CA, the spacer SPC may cover the pixel-defining layer PDL. In the connection area CA, the spacer SPC may be arranged to completely surround and cover the uppermost edges and the sidewall edges of the pixel-defining layer PDL. This may be because, as described above, the perimeter of the spacer opening SO in the connection area CA is arranged inside the perimeter of the connection opening PO-C of the pixel opening PO.

Referring to FIG. 11, the second angle a2 formed between the inner surface of the spacer SPC defining the spacer opening SO and the substrate 100 may be less than the first angle a1 formed between the inner surface of the pixel-defining layer PDL defining the pixel opening PO and the substrate 100. The second angle a2 may have a range of more than 0° and less than or equal to 80°. Accordingly, the opposite electrode 230 to be described below may cover the side surface of the spacer opening SO of the spacer SPC without being disconnected in the connection area CA, and the opposite electrodes 230 of adjacent pixels PX may be connected to each other.

A first intermediate layer 221 may be arranged on the first pixel electrode 211. A second intermediate layer 222 may be arranged on the second pixel electrode 212. The first intermediate layer 221 and the second intermediate layer 222 may each include a low-molecular weight or high-molecular weight material. The first intermediate layer 221 may include a first emission layer. The first emission layer may be arranged only inside the first pixel opening PO1. The second intermediate layer 222 may include a second emission layer. The second emission layer may be arranged only inside the second pixel opening PO2.

When the first intermediate layer 221 and the second intermediate layer 222 each include a low-molecular weight material, the first intermediate layer 221 and the second intermediate layer 222 may each have a structure in which a hole injection layer (HIL), a hole transport layer (HTL), an emission layer (EML), an electron transport layer (ETL), and an electron injection layer (EIL) are stacked in a single or composite structure, and may be formed by a vacuum deposition method.

When the first intermediate layer 221 and the second intermediate layer 222 each include a high-molecular weight material, the first intermediate layer 221 and the second intermediate layer 222 may each have a structure including an HTL and an EML. In this case, the HTL may include PEDOT, and the EML may include a polymer material, such as one or more of polyphenylene vinylene (PPV) and/or polyfluorene. The first intermediate layer 221 and the second intermediate layer 222 may be formed by screen printing, inkjet printing, laser induced thermal imaging (LITI), etc.

A first opposite electrode 231 may be arranged on the first intermediate layer 221. A second opposite electrode 232 may be arranged on the second intermediate layer 222. That is, the first intermediate layer 221 may be arranged between the first pixel electrode 211 and the first opposite electrode 231, and the second intermediate layer 222 may be arranged between the second pixel electrode 212 and the second opposite electrode 232.

The first opposite electrode 231 and the second opposite electrode 232 may each include a light-transmitting conductive layer including one or more of ITO, In₂O₃, and/or IZO, and may also include a semi-transmissive layer including a metal, such as one or more of Al and/or Ag. For example, the first opposite electrode 231 and the second opposite electrode 232 may each include a semi-transmissive layer including Mg or Ag. Although not shown in FIG. 11, a capping layer (not shown) may be located on the first opposite electrode 231 and the second opposite electrode 232. For example, the capping layer may include a single layer or multiple layers including a material selected from an organic material, an inorganic material, and a mixture thereof. In another embodiment, a LiF layer may be located on the capping layer. The first opposite electrode 231 and the second opposite electrode 232 may be simultaneously formed of the same material through the same process. Specifically, a material forming the first opposite electrode 231 and the second opposite electrode 232 may be deposited on the entire surface of the substrate 100.

The opposite electrode 230 may cover at least portions of the pixel-defining layer PDL and the spacer SPC. In the connection area CA, the spacer SPC is arranged inside the pixel opening PO of the pixel-defining layer PDL, and thus, as illustrated in FIG. 11, the opposite electrode 230 may be arranged along an inclined portion of the spacer SPC in the first-1 connection area CA1-1, the first-3 connection area CA1-3, the second-2 connection area CA2-2, and the second-4 connection area CA2-4.

The second angle a2 of the spacer SPC may be an acute angle, and thus, the opposite electrode 230 may cover the side surface of the spacer SPC. Accordingly, the first opposite electrode 231 may be connected to a remaining opposite electrode 230a, arranged on the upper surface of the spacer SPC, through the first connection area CA1, particularly the first-3 connection area CA1-3. The second opposite electrode 232 may be connected to the remaining opposite electrode 230a, arranged on the upper surface of the spacer SPC, through the second connection area CA2, particularly the second-2 connection area CA2-2. In addition, the first opposite electrode 231 may be connected to the second opposite electrode 232 through the first connection area CA1 and the second connection area CA2.

In this way, each of the opposite electrodes 230 arranged in a plurality of pixels PX may be connected to an adjacent opposite electrode 230 through the connection area CA, and thus, the display apparatus 10 may effectively transmit an electrical signal to the opposite electrodes 230.

In general, the opposite electrodes included in the plurality of display elements are integrally formed as a single body over the entire surface of the display area DA, and thus, the opposite electrodes included in the plurality of display elements may be electrically connected to each other. The same electrical signal may be supplied to the plurality of display elements through the opposite electrodes formed integrally. For example, the same common voltage ELVSS may be supplied to the plurality of display elements through the opposite electrodes formed integrally. Therefore, the opposite electrodes formed integrally may function as wiring that supplies the common voltage ELVSS to the display elements.

In an embodiment, the common voltage ELVSS may be supplied to the display elements by connecting the opposite electrodes 230 through the connection area CA described above.

An encapsulation layer 300 may be arranged to cover the organic light-emitting diode OLED. The encapsulation layer 300 may be arranged on the opposite electrode 230. The encapsulation layer 300 may include at least one organic encapsulation layer and at least one inorganic encapsulation layer. In an embodiment, the encapsulation layer 300 may include a first inorganic encapsulation layer 310, a second inorganic encapsulation layer 330, and an organic encapsulation layer 320 arranged therebetween.

The first inorganic encapsulation layer 310 and the second inorganic encapsulation layer 330 may each include one or more inorganic materials selected from one or more of aluminum oxide, titanium oxide, tantalum oxide, hafnium oxide, zinc oxide, silicon oxide, silicon nitride, and silicon oxynitride. The organic encapsulation layer 320 may include a polymer-based material. Examples of polymer-based materials may include one or more of an acrylic resin, an epoxy resin, polyimide, and polyethylene. In an embodiment, the organic encapsulation layer 320 may include acrylate. The organic encapsulation layer 320 may be formed by curing a monomer or applying a polymer. The organic encapsulation layer 320 may be transparent.

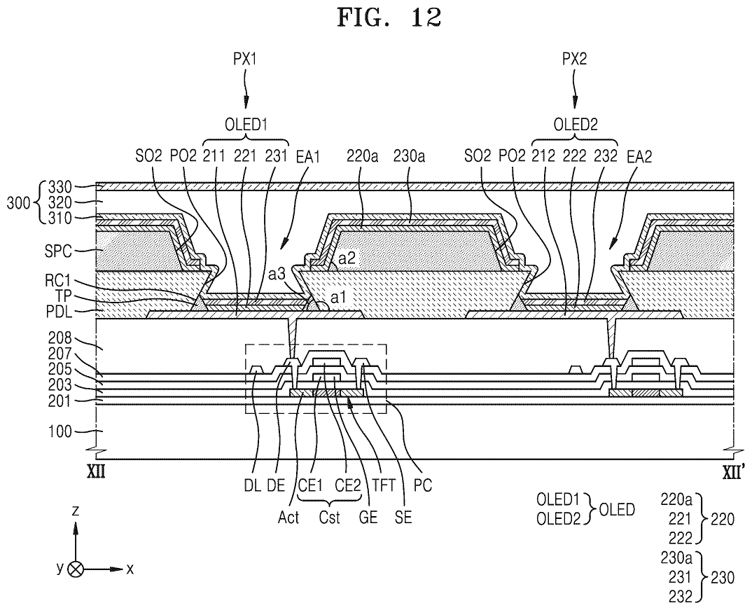

FIG. 12 is a schematic cross-sectional view of the display apparatus 10 taken along line XII-XII′ of FIG. 10. The following description focuses on parts different from those illustrated in FIG. 11, and redundant descriptions of the same configuration are omitted.

Referring to FIG. 12, the first organic light-emitting diode OLED1 and the second organic light-emitting diode OLED2 may be arranged to be separated from each other on the planarization layer 208. The first pixel electrode 211 and the second pixel electrode 212 may be arranged to be separated from each other on the planarization layer 208.

The first intermediate layer 221 may be arranged on the first pixel electrode 211. The second intermediate layer 222 may be arranged on the second pixel electrode 212. The first intermediate layer 221 and the second intermediate layer 222 may each include a low-molecular weight or high-molecular weight material.

In an embodiment, the first intermediate layer 221 of the first organic light-emitting diode OLED1 may include a first-1 common layer, a first emission layer, and a second-1 common layer. The first emission layer may include a high-molecular weight or low-molecular weight organic material that emits light of a certain color. The second intermediate layer 222 of the second organic light-emitting diode OLED2 may include a first-2 common layer, a second emission layer, and a second-2 common layer.

The first emission layer and the second emission layer may emit light of a certain wavelength band. For example, the first emission layer and the second emission layer may emit green, red, or blue light. The second emission layer of the second organic light-emitting diode OLED2 may emit light of a different wavelength band from the first emission layer of the first organic light-emitting diode OLED1.

The organic light-emitting diode OLED may have a tandem structure. Specifically, the organic light-emitting diode OLED may include a lower emission layer and an upper emission layer, and the upper emission layer may be arranged on the lower emission layer to overlap the lower emission layer. That is, the emission layer may include the lower emission layer and the upper emission layer.

A first common layer may be arranged between the pixel electrode 210 and the lower emission layer. The first common layer may have a single-layer or multi-layer structure. For example, when the first common layer includes a high-molecular weight material, the first common layer may include an HTL having a single-layer structure and may include one ore more of polyethylene dioxythiophene (PEDOT: poly-(3,4-ethylenedioxythiophene), polyaniline (PANI), N,N′-diphenyl-N,N′-bis(3-methylphenyl)-1,1′-bi-phenyl-4,4′-diamine (TPD), and/or N,N′-di(naphthalen-1-yl)-N,N′-diphenyl-benzidine (NPB). When the first common layer includes a low-molecular weight material, the first common layer may include an HIL and an HTL.

A second common layer may be arranged on the upper emission layer. The second common layer may not always be provided. For example, when the first common layer and the emission layer include a high-molecular weight material, it may be desirable to form a second common layer. The second common layer may have a single-layer or multi-layer structure. The second common layer may include an ETL and/or an EIL. An opposite electrode may be arranged on the second common layer.

An intermediate layer 220 may further include a charge generation layer. The charge generation layer may be located between the lower emission layer and the upper emission layer. The charge generation layer may supply charges to a first stack including the lower emission layer and a second stack including the upper emission layer.

The intermediate layer 220 may further include a third common layer and a fourth common layer. The third common layer may be located between the lower emission layer and the charge generation layer. The fourth common layer may be located between the charge generation layer and the upper emission layer. The third common layer may include an ETL, and the fourth common layer may include an HTL.

For example, the intermediate layer 220 may include a first common layer, a lower emission layer, a third common layer, a charge generation layer, a fourth common layer, an upper emission layer, and a second common layer.

The first opposite electrode 231 may be arranged on the first intermediate layer 221. The second opposite electrode 232 may be arranged on the second intermediate layer 222. That is, the first intermediate layer 221 may be arranged between the first pixel electrode 211 and the first opposite electrode 231, and the second intermediate layer 222 may be arranged between the second pixel electrode 212 and the second opposite electrode 232.

Referring to FIG. 12, the pixel-defining layer PDL may be arranged on the planarization layer 208. The pixel-defining layer PDL has a pixel opening PO that exposes at least a portion of the pixel electrode 210, and thus defines a pixel PX.

The pixel opening PO may include a first pixel opening PO1 that exposes at least a portion of the first pixel electrode 211, and a second pixel opening PO2 that exposes at least a portion of the second pixel electrode 212.

In an embodiment, the pixel-defining layer PDL may be provided in a reverse shape at the edge of the emission area EA. That is, the first angle a1 formed between the inner surface of the pixel-defining layer PDL defining the pixel opening PO and the upper surface of the substrate 100 may have a range of 90° or more and 170° or less. The pixel-defining layer PDL may be tapered toward the emission area EA as a distance increases upward from the substrate.

A spacer SPC may be arranged on the pixel-defining layer PDL. The spacer SPC may include a spacer opening SO exposing at least a portion of the pixel electrode 210. The spacer opening SO may include a first spacer opening SO1 exposing at least a portion of the first pixel electrode 211 and a second spacer opening SO2 exposing at least a portion of the second pixel electrode 212.

The spacer SPC may be provided in a normal shape on the pixel-defining layer PDL. The second angle a2 formed between the inner surface of the spacer SPC defining the spacer opening SO and the substrate 100 may be less than the first angle a1 formed between the inner surface of the pixel-defining layer PDL defining the pixel opening PO and the substrate 100. The second angle a2 may have a range of more than 0° and less than or equal to 80°.

Unlike in the connection area CA, the spacer SPC may not be arranged to cover the perimeter of the pixel-defining layer PDL at the edge of the emission area EA. That is, in an area excluding the connection area CA, the spacer SPC may cover a portion of the upper surface of the pixel-defining layer PDL. In the area excluding the connection area CA, the spacer SPC may be arranged outside the pixel opening PO, particularly, the first main opening PO-M. FIG. 12 shows a cross-sectional view along line XII-XII′ that crosses the emission area EA and does not pass through the connection area CA.

Accordingly, the peripheral edge of the pixel-defining layer PDL at the edge of the emission area EA may be exposed without being covered by the spacer SPC. This may be because, as described above, the spacer opening SO is formed to be larger than the pixel opening PO at the edge of the emission area EA.

In the area excluding the connection area CA, the first opposite electrode 231 may be separated from the remaining opposite electrode 230a arranged on the upper surface of the spacer SPC. In addition, the second opposite electrode 232 may be separated from the remaining opposite electrode 230a arranged on the upper surface of the spacer SPC. In other words, the opposite electrode 230 may be disconnected at the edge of the emission area EA.

In the area excluding the connection area CA, the first opposite electrode 231 and the second opposite electrode 232 may be separated from each other by being disconnected. In addition, the first intermediate layer 221 and the second intermediate layer 222 may be separated from each other by being disconnected. Accordingly, leakage current to adjacent pixels PX may be reduced.

As described above, the first intermediate layer 221 of the first organic light-emitting diode OLED1 and the second intermediate layer 222 of the second organic light-emitting diode OLED2 may include layers formed simultaneously with the same material through the same process. The first opposite electrode 231 of the first organic light-emitting diode OLED1 and the second opposite electrode 232 of the second organic light-emitting diode OLED2 may be formed simultaneously with the same material through the same process. In addition, the remaining opposite electrode 230a, the first opposite electrode 231, and the second opposite electrode 232 may be simultaneously formed with the same materials through the same processes. Specifically, the layers may be formed by depositing a material for forming the layers on the entire surface of the substrate. A leakage current may flow between the first organic light-emitting diode OLED1 and the second organic light-emitting diode OLED2 through the layers.

For example, it may be assumed that the first organic light-emitting diode OLED1 emits green light and the second organic light-emitting diode OLED2 emits red light. Even when trying to supply current only to the first organic light-emitting diode OLED1 that emits green light, current may also be supplied to the second organic light-emitting diode OLED2 by the layers that are formed integrally.

As a result, not only green light is emitted from the first organic light-emitting diode OLED1, but also red light is emitted from the second organic light-emitting diode OLED2, which may result in a decrease in color purity.

However, in the case of the display apparatus 10 according to the present embodiment, as described above, by controlling the first angle a1 of the pixel-defining layer PDL, the second angle a2 of the spacer SPC, and the arrangement relationship between the pixel-defining layer PDL and the spacer SPC, the layers that may be formed integrally may be separated from each other in an area other than the connection area CA, for example, around the emission area EA. In other words, it is possible to transmit an electrical signal through the connection area CA while preventing leakage current.

In an embodiment, the spacer SPC may include a tail portion TP. The tail portion TP may be a portion of the spacer SPC arranged within the spacer opening SO in a plan view. That is, the tail portion TP may include the same material as the spacer SPC and may be formed by the same process as the spacer SPC. In an embodiment, the tail portion TP may be separated inwardly from an edge of the spacer opening SO in a plan view and may extend along the edge of the spacer opening SO. Here, the “inwardly” may mean a direction toward the center of the pixel PX.

In this case, as illustrated in FIG. 12, the tail portion TP may be arranged inside the pixel opening PO. In an embodiment, the tail portion TP may be arranged between the pixel electrode 210 and the pixel-defining layer PDL. Specifically, the pixel-defining layer PDL may have a first concave portion RC1 at a portion that contacts the pixel electrode 210 around the pixel opening PO. That is, the pixel-defining layer PDL may define the first concave portion RC1 via an inclined portion formed by the pixel electrode 210 and the pixel-defining layer PDL that is arranged on the pixel electrode 210 and protrudes to be inclined in a reverse shape toward the emission area EA.

In an embodiment, the tail portion TP may be arranged in the first concave portion RC1 of the pixel-defining layer PDL. In a plan view, the tail portion TP may be covered by the pixel-defining layer PDL and not be exposed. The pixel-defining layer PDL may be arranged to protrude more than the tail portion TP toward the emission area EA. That is, in a plan view, the tail portion TP may be arranged outside the upper edge of the pixel-defining layer PDL defining the pixel opening PO (for example, may be arranged in a direction away from the center of the pixel opening PO).

In this case, in an embodiment, a third angle a3 formed between the inner side of the tail portion TP, which is a surface facing the center of the emission area EA, and the upper surface of the substrate 100 may have a range of about 30° to about 70°. Accordingly, the intermediate layer 220 and the opposite electrode 230 may be settled on the tail portion TP at the edge of the emission area EA, and the opposite electrode 230 may be formed to have a larger area than the intermediate layer 220 in the emission area EA. When the angle of the tail portion TP is greater than 70°, it may not be easy for the intermediate layer 220 and the opposite electrode 230 to be settled on the tail portion TP. When the angle of the tail portion TP is less than 30°, the size of the tail portion TP may be too small, and thus, the function of the tail portion TP may be deteriorated.

When there is no tail portion TP, the intermediate layer 220 may be deposited steeply toward the first concave portion RC1 of the pixel-defining layer PDL provided in a reverse shape, and the opposite electrode 230 may be deposited with a smaller area on the intermediate layer 220. This may cause a current-saturation phenomenon at the edge of the opposite electrode 230.

According to embodiments, the current-saturation phenomenon at the edge of the opposite electrode 230 may be reduced by providing the tail portion TP. As the intermediate layer 220 and the opposite electrode 230 are settled on the tail portion TP having a relatively low slope, which is arranged at the edge of the emission area EA, the resistance between the pixel electrode 210 and the opposite electrode 230 may gradually increase, and accordingly, the current-saturation phenomenon may not affect the intermediate layer 220, thereby preventing pixel defects.

In addition, in an embodiment, the width (e.g., the length in the x direction) of the tail portion TP may be 0.01 μm or more. In this case, the width of the tail portion TP may be less than the width of the inclined portion of the pixel-defining layer PDL. In addition, in an embodiment, the height (e.g., the length in the z direction) of the pixel-defining layer PDL from the pixel electrode 210 may be about 0.5 μm to about 4.5 μm. In this case, the height of the tail portion TP from the pixel electrode 210 may be 0.01 □ or more and may be less than ½ of the height of the pixel-defining layer PDL.

The tail portion TP may include the same material as the spacer SPC and may be formed by the same process as the spacer SPC. Specifically, as described above, the spacer SPC may include a positive photosensitive material. After the pixel-defining layer PDL is formed, an organic material including a positive photosensitive material may be applied on the pixel-defining layer PDL. The organic material may be filled inside the pixel opening PO and may also be arranged on the pixel-defining layer PDL. Next, an area corresponding to the spacer opening SO may be exposed. Because the organic material includes a positive photosensitive material, the exposed area corresponding to the spacer opening SO may be developed and removed. In this case, because the pixel-defining layer PDL is provided in a reverse shape, the organic material in the first concave portion RC1 of the pixel-defining layer PDL may be covered by the pixel-defining layer PDL so that the amount of light exposure may be small, and when the organic material is developed and removed, the tail portion TP may remain in the first concave portion RC1.

As described with reference to FIG. 11, an encapsulation layer 300 may be arranged on the opposite electrode 230. The encapsulation layer 300 may include a first inorganic encapsulation layer 310, a second inorganic encapsulation layer 330, and an organic encapsulation layer 320 arranged therebetween.

According to embodiments, cracks in the encapsulation layer 300 may be prevented through the tail portion TP. Specifically, as described above, the pixel-defining layer PDL may include a first concave portion RC1 at a portion that contacts the pixel electrode 210 around the pixel opening PO. The tail portion TP may be arranged in the first concave portion RC1 of the pixel-defining layer PDL. The first inorganic encapsulation layer 310 may cover at least a portion of the tail portion TP to directly contact the tail portion TP. Accordingly, the first inorganic encapsulation layer 310 may be arranged to cover the tail portion TP having a relatively low slope, thereby covering the opposite electrode 230, such as the first opposite electrode 231 and the second opposite electrode 232, at a gentler angle than the first concave portion RC1.

This may prevent cracks in the encapsulation layer 300, for example, the first inorganic encapsulation layer 310, compared to the case where there is no tail portion TP. When there is no tail portion TP, the first inorganic encapsulation layer 310 may be formed to have an angular shape in the first concave portion RC1. Therefore, cracks may occur in a portion having the angular shape in the first inorganic encapsulation layer 310 to form a moisture permeation path, thereby causing reliability defects. According to embodiments, cracks in the encapsulation layer 300 may be prevented and reliability may be improved, through the first inorganic encapsulation layer 310 gently formed in the first concave portion RC1.

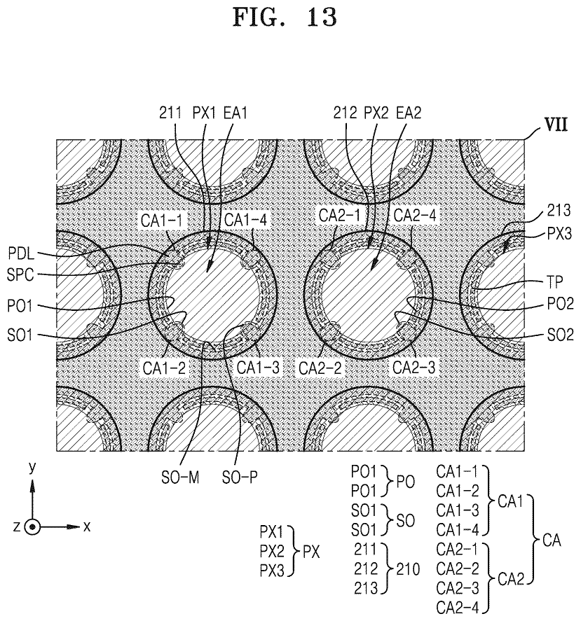

FIG. 13 is a schematic plan view of a portion of a display apparatus according to an embodiment, and may be similar to FIG. 10. The display apparatus according to the present embodiment is similar to the display apparatus described above, and thus only the differences will be described below.

Referring to FIG. 13, a plurality of pixels PX may be arranged on a substrate 100 of the display area DA. Each of the pixels PX may refer to a sub-pixel and may include a display element, such as an organic light-emitting diode OLED. The pixel PX may emit, for example, green light, red light, or blue light.

A plurality of pixel electrodes 210 may be arranged on the display area DA. The plurality of pixel electrodes 210 may include a first pixel electrode 211 included in the first pixel PX1, a second pixel electrode 212 included in the second pixel PX2, and a third pixel electrode 213 included in the third pixel PX3. For example, the first pixel electrode 211, the second pixel electrode 212, and the third pixel electrode 213 may be arranged to be separated from each other in a plan view. The first pixel electrode 211, the second pixel electrode 212, and the third pixel electrode 213 may have the same size, as illustrated in FIG. 13. In another embodiment, the first pixel electrode 211, the second pixel electrode 212, and the third pixel electrode 213 may have different sizes. For simplicity, the third pixel PX3 will not be described below.

In an embodiment, the pixel electrode 210 may have one of a circular shape and an annular shape. In another embodiment, the pixel electrode 210 may have an oval shape. The pixel electrode 210 may be larger than the pixel opening PO and the spacer opening SO.

In the display apparatus 10, an emission area EA and a connection area CA may be defined. The emission area EA is an area where light is emitted and may be an area overlapping the center of the pixel electrode 210. The connection area CA may be located at the edge of the emission area EA. At least one connection area CA may be provided in one pixel. For example, when the emission area EA has one of a substantially circular shape and a substantially annular shape, the connection area CA may be located apart from and along the perimeter of the emission area EA. The connection area CA may partially overlap the emission area EA.

The pixel-defining layer PDL may be arranged on the pixel electrode 210 and may include a pixel opening PO exposing at least a portion of the pixel electrode 210. The pixel opening PO may expose a central portion of the pixel electrode 210. In an embodiment, the pixel opening PO may have one of a circular shape and an annular shape. The pixel opening PO may be opened in one of a circular shape and an annular shape and may have a smaller size than the pixel electrode 210.

The pixel opening PO may include a first pixel opening PO1 arranged on the first pixel electrode 211 and a second pixel opening PO2 arranged on the second pixel electrode 212. The first pixel opening PO1 and the second pixel opening PO2 may have the same size, as illustrated in FIG. 13. In another embodiment, the first pixel opening PO1 and the second pixel opening PO2 may have different sizes.

The spacer SPC may be arranged on the pixel-defining layer PDL. The spacer SPC may include a spacer opening SO that exposes at least a portion of the pixel electrode 210. The spacer opening SO may expose a central portion of the pixel electrode 210.

In an embodiment, the spacer opening SO may be arranged to overlap the pixel opening PO. In an embodiment, in a plan view, the spacer opening SO may be formed to be larger than the perimeter of a portion of the pixel opening PO and smaller than the perimeter of another portion of the pixel opening PO. That is, in the emission area EA, the spacer opening SO may be larger than the pixel opening PO, and in the connection area CA, the spacer opening SO may be smaller than the pixel opening PO.

Specifically, the spacer opening SO may include a second main opening SO-M and a protruding opening SO-P. The second main opening SO-M corresponds to the emission area EA and may have one of an approximately circular shape and an approximately annular shape. The protruding opening SO-P corresponds to the connection area CA and may be an opening portion that protrudes inwardly from the perimeter of the second main opening SO-M. A plurality of protruding openings SO-P may be arranged to be separated from each other along the perimeter of the second main opening SO-M. In addition, in an embodiment, a plurality of protruding openings SO-P may be arranged at equal intervals along the perimeter of the second main opening SO-M.

In this case, in a plan view, the perimeter of the second main opening SO-M of the spacer opening SO may be arranged outside the perimeter of the pixel opening PO. That is, the second main opening SO-M may be larger than the pixel opening PO. In addition, in a plan view, the perimeter of the spacer opening SO, for example, the perimeter of the protruding opening SO-P, may be arranged inside the perimeter of the pixel opening PO.

In other words, a portion of the spacer SPC may protrude inwardly more than the pixel-defining layer PDL in the connection area CA. Here, the “inside” may mean a direction toward the center of the pixel.

The spacer opening SO may include a first spacer opening SO1 arranged on the first pixel electrode 211 and a second spacer opening SO2 arranged on the second pixel electrode 212. The first spacer opening SO1 and the second spacer opening SO2 may have the same size, as illustrated in FIG. 13. In another embodiment, the first spacer opening SO1 and the second spacer opening SO2 may have different sizes.

In an embodiment, the spacer SPC may include a tail portion TP. The tail portion TP may be a portion of the spacer SPC arranged within the spacer opening SO. In an embodiment, the tail portion TP may be separated inwardly from the perimeter of the spacer opening SO and may extend along the perimeter of the spacer opening SO.

In addition, in an embodiment, a plurality of tail portions TP may be provided, and each of the plurality of tail portions TP may be separated inwardly from the perimeter of the spacer opening SO and may extend along the edge of the spacer opening SO. In addition, the plurality of tail portions TP may be separated from each other with a protruding opening SO-P therebetween. In this case, the plurality of tail portions TP may be separated from each other without being connected to each other. That is, for example, four tail portions TP may be arranged in the spacer opening SO having one of a circular shape and an annular shape, and the four tail portions TP may be separated from each other without being connected to each other with the protruding opening SO-P of the spacer opening SO therebetween.

Where the second main opening SO-M corresponds to the emission area EA and may have one of an approximately circular shape and an approximately annular shape, each of the plurality of tail portions TP may be arced to correspond with the curvature of the second main opening SO-M.

In an embodiment, each of the tail portions TP may be arranged to overlap the pixel-defining layer PDL in a plan view. In other words, the tail portion TP may be arranged between the perimeter of the pixel opening PO and the perimeter of the spacer opening SO.

Although not shown in the drawings, according to the present embodiment, it will be understood that a cross-section of the display apparatus 10 taken along a line segment extending through the connection area CA, for example, extending diagonally in FIG. 13 is as illustrated in FIG. 11. In addition, it will be understood that a cross-section of the display apparatus 10 taken along a line segment extending through the connection area CA, for example, extending in the x direction in FIG. 13 is as illustrated in FIG. 12.

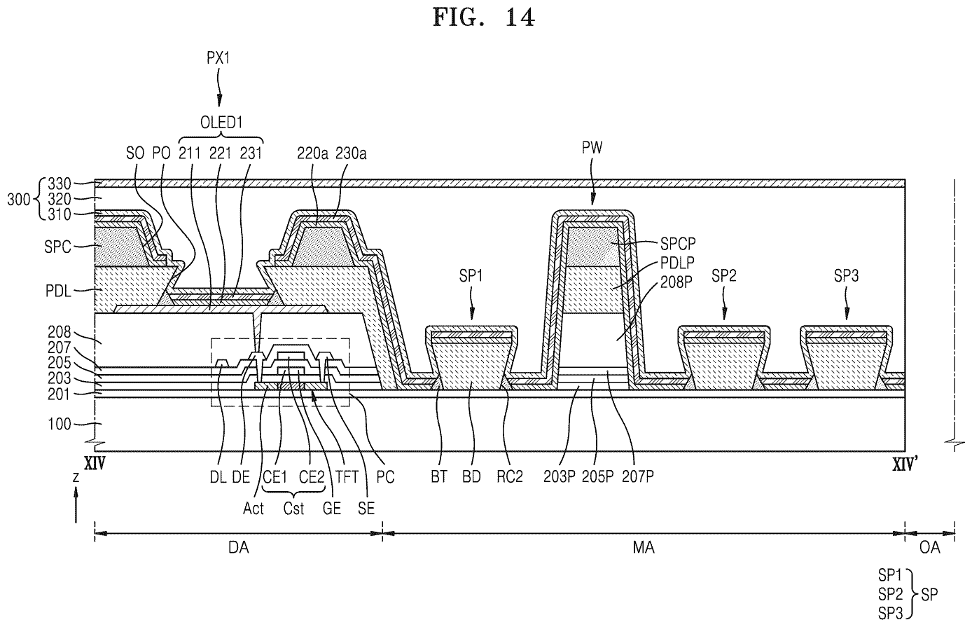

FIG. 14 is a schematic cross-sectional view of the display apparatus 10 taken along line XIV-XIV′ of FIG. 6. Hereinafter, differences from the embodiments described above will be described, and redundant descriptions of the same configuration are omitted.

Referring to the intermediate area MA of FIGS. 6 and 14, a partition wall PW and separators SP may be arranged to be separated from each other between the display area DA and the opening area OA. For example, at least one partition wall PW may be arranged in the intermediate area MA, and at least one separator SP may be arranged between the partition wall PW and the display area DA and between the partition wall PW and the opening area OA. In addition, in a plan view, the partition wall PW and the separators SP may be arranged along the perimeter of the opening area OA. FIG. 14 illustrates an example in which one partition wall PW is arranged, one separator SP is arranged between the partition wall PW and the display area DA, and two separators SP are arranged between the partition wall PW and the opening area OA. In this case, the separators SP may be defined as a first separator SP1, a second separator SP2, and a third separator SP3 in the order of their proximity to the display area DA.

In an embodiment, the partition wall PW may be arranged on the upper surface of a buffer layer 201. In an embodiment, the partition wall PW may include a portion 203P of a gate insulating layer 203, a portion 205P of a first interlayer insulating layer 205, and a portion 207P of a second interlayer insulating layer 207. In addition, a portion 208P of a planarization layer 208, a portion PDLP of a pixel-defining layer PDL, and a portion SPCP of a spacer SPC may be arranged above a portion 207P of the second interlayer insulating layer 207. That is, the partition wall PW may include a structure in which the gate insulating layer 203, the first interlayer insulating layer 205, the second interlayer insulating layer 207, the planarization layer 208, the pixel-defining layer PDL, and the spacer SPC are stacked. However, layers included in the partition wall PW are not limited thereto, and some of the other layers may be further included in the partition wall PW or some of the layers may be omitted.

The separators SP may be arranged on the upper surface of the buffer layer 201. For example, the separators SP may be arranged on the upper surface of the buffer layer 201 to be separated from each other in a direction parallel to the upper surface of the substrate 100. In an embodiment, each of the separators SP may include a body portion BD and a body tail portion BT.

The body portion BD may include the same material as the pixel-defining layer PDL described above and may be formed by the same process as the pixel-defining layer PDL. Accordingly, the body portion BD may be formed in a reverse shape like the pixel-defining layer PDL described above, and may include a second concave portion RC2 formed at a portion of the body portion BD that contacts the buffer layer 201 around the body portion BD. That is, the body portion BD may define the second concave portion RC2 via an inclined portion formed by the buffer layer 201 and the body portion BD that is arranged on the buffer layer 201 and protrudes to be inclined in a reverse shape. In addition, it will be understood that the angle formed between an inclined perimeter of the body portion BD and the upper surface of the substrate 100 may be the same as the first angle.

The body tail portion BT may be arranged in the second concave portion RC2 of the body portion BD. The body tail portion BT may include the same material as the spacer SPC described above and may be formed by the same process as the spacer SPC. Accordingly, the body tail portion BT may be arranged in the second concave portion RC2 similarly to the tail portion TP described above. In addition, in a plan view, the body tail portion BT may be covered by the body portion BD and not exposed. The body portion BD may be arranged to protrude outwardly more than the body tail portion BT. That is, in a plan view, the body tail portion BT may be arranged inside the upper surface edge of the body portion BD. In addition, it will be understood that the angle formed between the outer surface of the body tail portion BT and the upper surface of the substrate 100 may be equal to the third angle.

According to embodiments, the display apparatus 10 may block moisture, etc. from progressing into the display area DA by providing a separator SP. As described above, the separator SP may be provided in a reverse shape, and may disconnect, from the upper surface of the separator SP, the intermediate layer 220 and the opposite electrode 230 deposited on the entire surface of the display apparatus 10. Accordingly, moisture, etc. flowing into the opening area OA may be prevented from moving toward the display area DA through organic layers, for example, the intermediate layer 220.

In addition, because the separator SP is formed simultaneously with the pixel-defining layer PDL and the spacer SPC through the processes of forming the pixel-defining layer PDL and the spacer SPC, a separate process for forming the separator SP is not required, and thus, the number of process steps may be reduced.

In addition, as described with reference to FIG. 12, cracks in the encapsulation layer 300 may be prevented through the body tail portion BT. Specifically, the body tail portion BT may be arranged in the second concave portion RC2. The first inorganic encapsulation layer 310 may cover at least a portion of the body tail portion BT to be in direct contact with the body tail portion BT. Accordingly, the first inorganic encapsulation layer 310 may be arranged to cover the body tail portion BT having a relatively low inclination, and may cover the opposite electrode 230 at a gentler angle than the second concave portion RC2.

This case may prevent cracks in the encapsulation layer 300, for example, the first inorganic encapsulation layer 310, compared to the case where there is no body tail portion BT. When there is no body tail portion BT, the first inorganic encapsulation layer 310 may be formed to have an angular shape in the second concave portion RC2. Therefore, cracks may occur in a portion having the angular shape in the first inorganic encapsulation layer 310 to form a moisture permeation path, thereby causing reliability defects. According to embodiments, cracks in the encapsulation layer 300 may be prevented and reliability may be improved, through the first inorganic encapsulation layer 310 gently formed in the second concave portion RC2.

One or more embodiments described above may provide a display apparatus and electronic device capable of reducing leakage current, minimizing process steps, and preventing current concentration phenomenon.

The effects of the disclosure are not limited to the effects mentioned above, and other effects not mentioned will be clearly understood by those of ordinary skill in the art from the description of the claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a pixel electrode arranged on the substrate and comprising an emission area and a connection area;
a pixel-defining layer having a pixel opening exposing the emission area;
a spacer arranged on the pixel-defining layer and having a spacer opening overlapping the pixel opening and exposing the emission area; and
an intermediate layer and an opposite electrode, which cover the spacer and which cover the pixel electrode exposed by the pixel opening and the spacer opening,
wherein the connection area is arranged on a portion of a perimeter of the emission area, and
wherein, in the emission area, the spacer opening is larger than the pixel opening, and in the connection area, the spacer opening is smaller than the pixel opening.

2. The display apparatus of claim 1, wherein the pixel opening comprises:
a first main opening overlapping the emission area; and
a connection opening overlapping the connection area,
wherein the connection opening extends outward from the first main opening.

3. The display apparatus of claim 2, wherein the first main opening has a polygonal shape, and the connection opening is arranged at a corner of the polygonal shape.

4. The display apparatus of claim 2, wherein, in a plan view, a perimeter of the spacer opening crosses the connection opening.

5. The display apparatus of claim 1, wherein the spacer is not arranged in the emission area, and a portion of the spacer is arranged in the connection area.

6. The display apparatus of claim 1, wherein the spacer opening comprises:
a second main opening overlapping the emission area; and
a protruding opening overlapping the connection area,
wherein the protruding opening protrudes inwardly from a perimeter of the second main opening and the second main opening has one of a circular shape and an annular shape, and a plurality of protruding openings are separated from each other along a perimeter of the second main opening.

7. The display apparatus of claim 1, wherein the spacer comprises a tail portion that separated inwardly from a perimeter of the spacer opening in a plan view and extends along the perimeter of the spacer opening and the tail portion is arranged on the perimeter of the emission area and is not arranged in the connection area.

8. The display apparatus of claim 1, wherein the spacer comprises a tail portion that separated inwardly from a perimeter of the spacer opening in a plan view and extends along the perimeter of the spacer opening and, in a plan view, the tail portion is arranged between the perimeter of the spacer opening and a perimeter of the pixel opening.

9. A display apparatus comprising:
a substrate;
a pixel electrode arranged on the substrate and comprising an emission area and a connection area;
a pixel-defining layer having a pixel opening exposing the emission area;
a spacer arranged on the pixel-defining layer and having a spacer opening overlapping the pixel opening and exposing the emission area; and
an intermediate layer and an opposite electrode, which cover the spacer and which cover the pixel electrode exposed by the pixel opening and the spacer opening,
wherein the connection area is arranged on a portion of a perimeter of the emission area, and
wherein the spacer is arranged on a portion of an upper surface of the pixel-defining layer around the perimeter of the emission area, and the spacer is arranged in the connection area to completely cover the upper surface and side surfaces of the pixel-defining layer.

10. The display apparatus of claim 9, wherein the pixel-defining layer is tapered in a reverse shape to be inclined toward a center of the emission area as a distance increases upward from the substrate and a first angle formed between an inner surface of the pixel-defining layer defining the pixel opening and an upper surface of the substrate is in a range of about 90° to about 170°.

11. The display apparatus of claim 9, wherein the spacer is tapered in a normal shape to be inclined in a direction away from a center of the emission area as a distance increases upward from the substrate and a second angle formed between an inner surface of the spacer defining the spacer opening and the substrate is in a range of more than 0° and less than or equal to 80°.

12. The display apparatus of claim 9, wherein the intermediate layer and the opposite electrode are disconnected at the perimeter of the emission area, so that a portion of the intermediate layer arranged on the pixel electrode is separated from a portion of the intermediate layer arranged on an upper surface of the spacer, and a portion of the opposite electrode arranged on the pixel electrode is separated from a portion of the opposite electrode arranged on the upper surface of the spacer.

13. The display apparatus of claim 9, wherein the intermediate layer and the opposite electrode cover a side surface of the spacer opening in the connection area, a portion of the intermediate layer arranged on the pixel electrode is connected to a portion of the intermediate layer arranged on an upper surface of the spacer, and a portion of the opposite electrode arranged on the pixel electrode is connected to a portion of the opposite electrode arranged on the upper surface of the spacer.

14. The display apparatus of claim 9, wherein the spacer comprises a tail portion arranged inside the pixel opening along the perimeter of the emission area and the tail portion is arranged between a side surface of the pixel-defining layer defining the pixel opening and the pixel electrode, a third angle formed between a side surface of the tail portion facing a center of the emission area and an upper surface of the substrate is in a range of about 30° to about 70° and, in the emission area, the intermediate layer and the opposite electrode are settled on the side surface of the tail portion.

15. A display apparatus comprising:
a substrate comprising a first area, a second area surrounding at least a portion of the first area, and a third area between the first area and the second area;
a pixel electrode arranged in the second area;
a pixel-defining layer having a pixel opening exposing a portion of the pixel electrode;
a spacer arranged on the pixel-defining layer and having a spacer opening overlapping the pixel opening;
an intermediate layer arranged on the spacer; and
a separator arranged in the third area,
wherein the separator comprises:
a body portion in a reverse shape, which is arranged on the substrate; and
a body tail portion arranged between an inclined side surface of the body portion and the substrate.

16. The display apparatus of claim 15, wherein the body portion comprises a same material as the pixel-defining layer and the body tail portion comprises a same material as the spacer.

17. The display apparatus of claim 15, wherein the intermediate layer is disconnected or separated by the separator in the third area.

18. An electronic device comprising:
the display apparatus of claim 15; and
a housing accommodating the display apparatus therein.

19. The electronic device according to claim 18, wherein:
multiple separators are arranged in the third area,
the display apparatus of claim 15 further comprises a partition wall interposed between neighboring ones of the multiple separators, and
the partition wall comprises a portion of a gate insulating layer, a portion of a first interlayer insulating layer, and a portion of a second interlayer insulating layer.

20. The electronic device of claim 19, wherein the partition wall further comprises a portion of a planarization layer, a portion of a pixel-defining layer and a portion of a spacer above the portion of the second interlayer insulating layer.
